(19) United States
(12) Patent Application Publication
(10) Pub. No.: US 2026/0322325 A1
(43) Pub. Date: Oct. 15, 2026

(54) CIRCUIT DEVICE AND OSCILLATOR

(71) Applicant: SEIKO EPSON CORPORATION, Tokyo (JP)

(72) Inventor: Wataru Okumura, Minamiminowa-mura (JP)

(21) Appl. No.: 19/461,138

(22) Filed: Jan. 27, 2026

(30) Foreign Application Priority Data
Jan. 29, 2025 (JP) 2025-012563

(51) Int. Cl. H03B 5/04; H03F 3/45

(52) U.S. Cl. CPC H03B 5/04; H03F 3/45085; H03F 3/45174

(57) ABSTRACT

A circuit device includes an oscillation circuit that generates an oscillation signal by causing a resonator to oscillate, a temperature compensation circuit that includes a higher-order correction circuit which generates a higher-order compensation current based on a temperature detection voltage from a temperature detection circuit, and that generates a temperature compensation voltage of an oscillation frequency of the oscillation signal based on the higher-order compensation current, and a tail current control circuit. The higher-order correction circuit includes a differential pair circuit that generates a current for temperature compensation based on the temperature detection voltage by controlling a tail current via the tail current control circuit. The tail current control circuit controls the tail current to reach a minimum current value at a temperature of an inflection point of the temperature compensation voltage and to have a current value that increases in accordance with a change in a temperature from the temperature of the inflection point.

The present application is based on, and claims priority from JP Application Serial Number 2025-012563, filed Jan. 29, 2025, the disclosure of which is hereby incorporated by reference herein in its entirety.

### BACKGROUND

### 1. Technical Field

The present disclosure relates to a circuit device and an oscillator and the like.

### 2. Related Art

A circuit device that causes a resonator such as a quartz crystal resonator to oscillate performs temperature compensation of an oscillation frequency. For example, JP-A-2023-90099 discloses a circuit device that performs such temperature compensation. For example, a temperature compensation circuit generates a temperature compensation current using a differential pair circuit and performs temperature compensation of the oscillation frequency using the temperature compensation current.

However, a method of appropriately controlling a tail current flowing through the differential pair circuit in accordance with reduction in a power supply voltage, reduction in power consumption, and the like is not suggested.

### SUMMARY

According to an aspect of the present disclosure, a circuit device includes an oscillation circuit that generates an oscillation signal by causing a resonator to oscillate, a temperature compensation circuit that includes a higher-order correction circuit which generates a higher-order compensation current based on a temperature detection voltage from a temperature detection circuit, and that generates a temperature compensation voltage of an oscillation frequency of the oscillation signal based on the higher-order compensation current, and a tail current control circuit, in which the higher-order correction circuit includes a differential pair circuit that generates a current for temperature compensation based on the temperature detection voltage by controlling a tail current via the tail current control circuit, and the tail current control circuit controls the tail current to reach a minimum current value at a temperature of an inflection point of the temperature compensation voltage and to have a current value that increases in accordance with a change in a temperature from the temperature of the inflection point.

According to another aspect of the present disclosure, an oscillator includes the above circuit device, and the resonator.

### BRIEF DESCRIPTION OF THE DRAWINGS

FIG. 1 is a configuration example of a circuit device of the present embodiment.

FIG. 2 is a detailed configuration example of the circuit device and an oscillator of the present embodiment.

FIG. 3 is a configuration example of a temperature compensation circuit.

FIG. 4 is a descriptive diagram of a temperature compensation process.

FIG. 5 is a configuration example of a compensation circuit of a higher-order correction circuit.

FIG. 6 is a descriptive diagram of a method of generating a temperature compensation current.

FIG. 7 is a configuration example of a temperature detection circuit.

FIG. 8 is another configuration example of the temperature detection circuit.

FIG. 9 is a configuration example of the temperature detection circuit and the temperature compensation circuit.

FIG. 10 is an example of temperature characteristics of a temperature detection voltage and a reference voltage.

FIG. 11 is a configuration example of a differential pair circuit.

FIG. 12 is an example of a temperature characteristic of a current flowing through the differential pair circuit on a low-temperature side.

FIG. 13 is an example of a temperature characteristic of a current flowing through the differential pair circuit on a high-temperature side.

FIG. 14 is an example of the temperature characteristic of the temperature detection voltage.

FIG. 15 is an example of a temperature characteristic of a current for temperature compensation.

FIG. 16 is an example of the temperature characteristic of the current for temperature compensation.

FIG. 17 is a configuration example of a tail current control circuit.

FIG. 18 is an example of a temperature characteristic for describing an operation of the tail current control circuit.

FIG. 19 is a descriptive diagram of an effect of causing a tail current to have a temperature characteristic.

FIG. 20 is a descriptive diagram of the effect of causing the tail current to have the temperature characteristic.

FIG. 21 is another configuration example of the tail current control circuit.

### DESCRIPTION OF EMBODIMENTS

Hereinafter, the present embodiment will be described. The present embodiment described below does not unduly limit the contents described in the claims. In addition, not all configurations described in the present embodiment are essential components.

### 1. Circuit Device

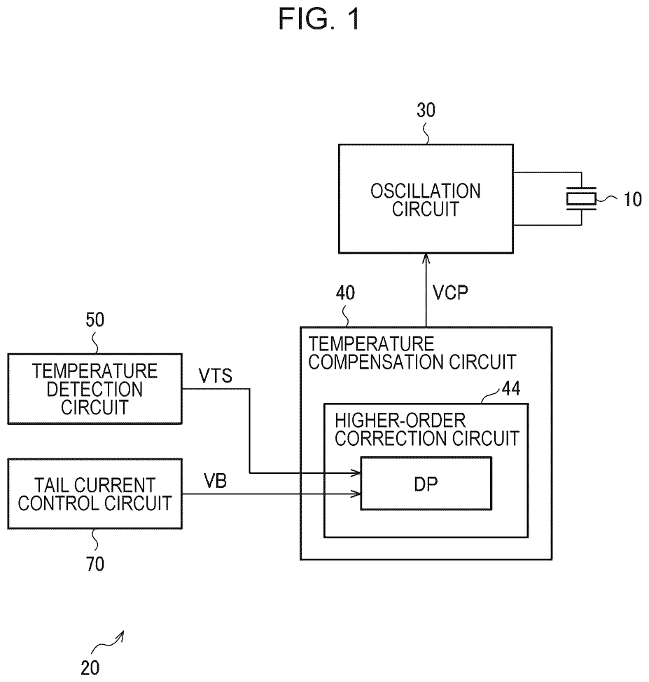

FIG. 1 shows a configuration example of a circuit device 20 according to the present embodiment. The circuit device 20 of the present embodiment includes an oscillation circuit 30, a temperature compensation circuit 40, and a tail current control circuit 70. The circuit device 20 can also include a temperature detection circuit 50. A resonator 10 is electrically coupled to the circuit device 20. For example, the resonator 10 and the circuit device 20 constitute an oscillator. The circuit device 20 is not limited to the configuration in FIG. 1, and various modifications such as omitting some of the components, adding other components, or replacing some of the components with other components can be made.

The resonator 10 is an element that generates mechanical resonation via an electrical signal. The resonator 10 can be implemented by, for example, a resonator element such as a quartz crystal resonator element. For example, the resonator 10 can be implemented by a quartz crystal resonator element that resonates in a thickness shear mode with a cut angle such as AT cut or SC cut, by a tuning fork type quartz crystal resonator element, or by a double tuning fork type quartz crystal resonator element. For example, the resonator 10 may be a resonator incorporated into a temperature compensated crystal oscillator (TCXO) not including a crystal oven or a resonator incorporated into an oven controlled crystal oscillator (OCXO) including a crystal oven. The resonator 10 of the present embodiment can also be implemented by various resonator elements such as a resonator element of a type other than a thickness shear resonation type, a tuning fork type, or a double tuning fork type, and a piezoelectric resonator element formed of a material other than quartz crystal. For example, a surface acoustic wave (SAW) resonator or a micro electro mechanical systems (MEMS) resonator as a silicon resonator formed using a silicon substrate can be adopted as the resonator 10.

The circuit device 20 is an integrated circuit device called an integrated circuit (IC). For example, the circuit device 20 is an IC manufactured through a semiconductor process and is a semiconductor chip in which a circuit element is formed at a semiconductor substrate. The circuit device 20 operates based on an externally supplied power supply voltage.

The oscillation circuit 30 is a circuit that causes the resonator 10 to oscillate. For example, the oscillation circuit 30 generates an oscillation signal by causing the resonator 10 to oscillate. The oscillation signal is, for example, an oscillation clock signal. For example, the oscillation circuit 30 can be implemented by a drive circuit for oscillation electrically coupled to one end and the other end of the resonator 10, or a passive element such as a capacitor or a resistor. The drive circuit can be implemented by, for example, a CMOS inverter circuit or a bipolar transistor. The drive circuit is a core circuit of the oscillation circuit 30. The drive circuit causes the resonator 10 to oscillate by voltage-driving or current-driving the resonator 10. For example, various types of oscillation circuits such as an inverter type, a Pierce type, a Colpitts type, and a Hartley type can be used as the oscillation circuit 30. Coupling in the present embodiment is electrical coupling. Electrical coupling is coupling through which an electrical signal can be transmitted, and is coupling through which information can be transmitted by an electrical signal. Electrical coupling may be coupling via a passive element and the like.

The temperature detection circuit 50 is a sensor circuit that detects a temperature. Specifically, the temperature detection circuit 50 outputs a temperature-dependent voltage that changes in accordance with an ambient temperature as a temperature detection voltage VTS. For example, the temperature detection circuit 50 generates the temperature detection voltage VTS that is a temperature detection signal using a circuit element having temperature dependence. Specifically, the temperature detection circuit 50 outputs the temperature detection voltage VTS of which a voltage changes depending on a temperature using, for example, temperature dependence of a forward voltage of a P-N junction. A modification of using a digital temperature detection circuit as the temperature detection circuit 50 can also be made. In this case, the temperature detection voltage VTS may be generated by performing D/A conversion on temperature detection data.

The temperature compensation circuit 40 performs temperature compensation of an oscillation frequency of the oscillation circuit 30. For example, the temperature compensation circuit 40 outputs a temperature compensation voltage VCP of the oscillation frequency of the oscillation signal to the oscillation circuit 30 based on the temperature detection voltage VTS from the temperature detection circuit 50. Temperature compensation is, for example, a process of compensating by reducing a change in the oscillation frequency caused by a change in the temperature. That is, the temperature compensation circuit 40 performs temperature compensation of the oscillation frequency of the oscillation circuit 30 to obtain a constant oscillation frequency even when the temperature changes. A modification of digitally adjusting the oscillation frequency in a variable capacitance circuit of the oscillation circuit 30 using temperature compensation data obtained by performing A/D conversion on the temperature compensation voltage VCP can also be made.

The temperature compensation circuit 40 includes a higher-order correction circuit 44, and the higher-order correction circuit 44 generates a higher-order compensation current based on the temperature detection voltage VTS from the temperature detection circuit 50. The temperature compensation circuit 40 generates the temperature compensation voltage VCP of the oscillation frequency of the oscillation signal based on the higher-order compensation current. For example, when the temperature compensation voltage VCP is approximated by a higher-order polynomial, the higher-order correction circuit 44 generates a higher-order compensation current corresponding to a higher-order term of the polynomial. The temperature compensation circuit 40 generates the temperature compensation voltage VCP by performing current-to-voltage conversion on the temperature compensation current obtained by adding a first-order compensation current corresponding to a first-order term of the polynomial and the higher-order compensation current.

The higher-order correction circuit 44 includes a differential pair circuit DP. The differential pair circuit DP generates a current for temperature compensation based on the temperature detection voltage VTS by controlling a tail current via the tail current control circuit 70. The higher-order compensation current is generated based on the current for temperature compensation generated by the differential pair circuit DP.

The tail current control circuit 70 controls the tail current flowing through the differential pair circuit DP. The tail current is also called a bias current. For example, the differential pair circuit DP includes a first transistor and a second transistor constituting a differential pair, and a transistor of a current source for causing a current to flow through the first transistor and the second transistor. The first transistor of the differential pair is controlled by, for example, inputting the temperature detection voltage VTS into its base or gate, and the second transistor of the differential pair is controlled by, for example, inputting a reference voltage into its base or gate. The tail current control circuit 70 controls the tail current flowing through the transistor of the current source. For example, a current obtained by adding the current flowing through the first transistor and the current flowing through the second transistor of the differential pair is the tail current. For example, the tail current control circuit 70 controls the tail current by outputting a bias voltage VB for causing the tail current to flow through the transistor of the current source to a gate or a base of the transistor of the current source.

In the present embodiment, the tail current control circuit 70 controls the tail current to reach a minimum current value at a temperature of an inflection point of the temperature compensation voltage VCP and to have a current value that increases in accordance with a change in the temperature from the temperature of the inflection point. The temperature of the inflection point is, for example, a typical temperature and is, for example, 25° C. For example, the temperature compensation voltage VCP is set to reach, for example, a reference voltage VRC, described later, at the temperature of the inflection point. For example, the higher-order compensation current is set to have a current value that reaches the minimum current value such as zero at the temperature of the inflection point. The temperature compensation voltage VCP changes with reference to the reference voltage VRC in response to a change in the temperature. For example, the temperature compensation voltage VCP changes to a positive side with respect to the reference voltage VRC or changes to a negative side with respect to the reference voltage VRC in accordance with a change in the temperature.

The tail current control circuit 70 controls the tail current of the differential pair circuit DP to reach the minimum current value at the temperature of the inflection point. The minimum current value is, for example, a current value of zero but may be a current value greater than zero. Even when the tail current control circuit 70, for example, sets the tail current to reach, for example, the minimum current value such as zero at the temperature of the inflection point, a current higher than the minimum current value may flow through the transistor of the current source via a leakage current of the transistor of the current source of the differential pair circuit.

The tail current control circuit 70 controls the tail current to have a current value that increases in accordance with a change in the temperature from the temperature of the inflection point. For example, the tail current control circuit 70 controls the tail current of the differential pair circuit DP such that the tail current increases from the minimum current value as the temperature decreases from the temperature of the inflection point. Alternatively, the tail current control circuit 70 controls the tail current of the differential pair circuit DP such that the tail current increases from the minimum current value as the temperature increases from the temperature of the inflection point.

In the present embodiment, the tail current flowing through the differential pair circuit DP of the higher-order correction circuit 44 is controlled to reach the minimum current value at the temperature of the inflection point. Accordingly, the higher-order compensation current generated by the current of the differential pair circuit DP can be set to the minimum current value such as zero at the temperature of the inflection point, and adjustment of the inflection point can be facilitated. In addition, the tail current flowing through the differential pair circuit DP of the higher-order correction circuit 44 is controlled to have a current value that increases in accordance with a change in the temperature. Accordingly, for example, by causing the tail current to have a temperature characteristic, the higher-order correction circuit 44 can correctly generate the higher-order compensation current even when a gain of a temperature characteristic of the temperature detection voltage VTS of the temperature detection circuit 50 is reduced because of a factor such as reduction in the power supply voltage of the circuit device 20. In addition, by controlling the tail current to reach the minimum current value at the temperature of the inflection point and to have a current value that increases in accordance with a change in the temperature, an unnecessary current flowing through the differential pair circuit DP can be reduced, and reduction in power consumption of the circuit device 20 can be implemented.

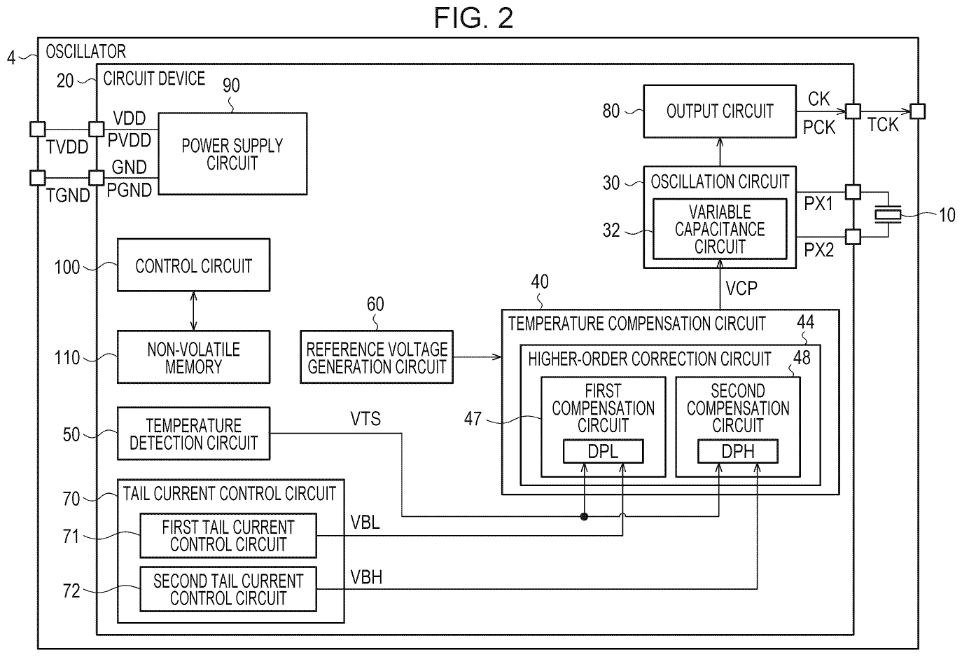

FIG. 2 shows a detailed configuration example of the circuit device 20 and an oscillator 4 of the present embodiment. In FIG. 2, the circuit device 20 includes the temperature detection circuit 50, a reference voltage generation circuit 60, an output circuit 80, a power supply circuit 90, a control circuit 100, and a non-volatile memory 110, in addition to the oscillation circuit 30, the temperature compensation circuit 40, and the tail current control circuit 70. The oscillator 4 includes the resonator 10 and the circuit device 20, and the resonator 10 is electrically coupled to the circuit device 20. The resonator 10 and the circuit device 20 are electrically coupled using, for example, internal wiring of a package accommodating the resonator 10 and the circuit device 20, a bonding wire, or a metal bump. The circuit device 20 and the oscillator 4 are not limited to the configuration in FIG. 2, and various modifications such as omitting some of the components, adding other components, or replacing some of the components with other components can be made.

The circuit device 20 also includes pads PVDD, PGND, PX1, PX2, and PCK. The pads are terminals of the circuit device 20 which is a semiconductor chip. For example, in a pad region, a metal layer is exposed from a passivation film that is an insulating layer, and the pads which are the terminals of the circuit device 20 are configured with the exposed metal layer. The pads PVDD and PGND are a power supply pad and a ground pad, respectively. A power supply voltage VDD from an external power supply device is supplied to the pad PVDD. The pad PGND is a pad to which GND that is a ground voltage is supplied. The ground voltage is, for example, a ground potential. In the present embodiment, GND will be referred to as VSS as appropriate. For example, VDD corresponds to a high-potential side power supply, and VSS which is GND corresponds to a low-potential side power supply. The pads PX1 and PX2 are pads for coupling of the resonator 10. The pad PCK is a pad for outputting a clock signal CK. The pads PVDD, PGND, and PCK are electrically coupled to terminals TVDD, TGND, and TCK, respectively, that are external terminals for external coupling of the oscillator 4. The pads and the terminals are electrically coupled to each other using, for example, internal wiring of a package, a bonding wire, or a metal bump. A terminal and a pad into which an external control voltage is input may be provided so that an external system can control the oscillation frequency via the control voltage.

The oscillation circuit 30 is electrically coupled to the resonator 10 via the pads PX1 and PX2. The pads PX1 and PX2 are pads for resonator coupling. The drive circuit for oscillation of the oscillation circuit 30 is provided between the pad PX1 and the pad PX2. The oscillation circuit 30 includes a variable capacitance circuit 32. The variable capacitance circuit 32 is, for example, a circuit that changes capacitance at at least one of one end or the other end of the resonator 10. The oscillation frequency of the oscillation circuit 30 can be adjusted by adjusting the capacitance of the variable capacitance circuit 32. That is, load capacitance of the oscillation circuit 30 can be variably adjusted by electrically coupling the variable capacitance circuit 32 to at least one of the pads PX1 and PX2. The variable capacitance circuit 32 can be implemented by, for example, a variable capacitance element such as a varactor. For example, the variable capacitance circuit 32 is configured with at least one variable capacitance element.

The temperature compensation circuit 40 performs analog temperature compensation via, for example, polynomial approximation. For example, when the temperature compensation voltage VCP for compensating a frequency-temperature characteristic of the resonator 10 is approximated by a polynomial, the temperature compensation circuit 40 performs analog temperature compensation based on coefficient information of the polynomial. Analog temperature compensation is temperature compensation implemented by, for example, a process of adding a current signal or a voltage signal which is an analog signal. For example, when the temperature compensation voltage VCP is approximated by a higher-order polynomial, a zeroth-order coefficient, a first-order coefficient, and a higher-order coefficient of the polynomial are stored in a storage unit implemented by, for example, the non-volatile memory 110 as zeroth-order correction data, first-order correction data, and higher-order correction data, respectively. The higher-order coefficient is, for example, a coefficient of a higher order higher than the first order, and the higher-order correction data is correction data corresponding to the higher-order coefficient. For example, when the temperature compensation voltage VCP is approximated by a third-order polynomial, the zeroth-order coefficient, the first-order coefficient, the second-order coefficient, and the third-order coefficient of the polynomial are stored in the storage unit as the zeroth-order correction data, the first-order correction data, second-order correction data, and third-order correction data. The temperature compensation circuit 40 performs temperature compensation based on the zeroth-order correction data to the third-order correction data. In this case, the second-order correction data and temperature compensation based on the second-order correction data may be omitted. In addition, for example, when the temperature compensation voltage VCP is approximated by a fifth-order polynomial, the zeroth-order coefficient, the first-order coefficient, the second-order coefficient, the third-order coefficient, the fourth-order coefficient, and the fifth-order coefficient of the polynomial are stored in the storage unit as the zeroth-order correction data, the first-order correction data, the second-order correction data, the third-order correction data, fourth-order correction data, and fifth-order correction data. The temperature compensation circuit 40 performs temperature compensation based on the zeroth-order correction data to the fifth-order correction data. In this case, the second-order correction data or the fourth-order correction data, and temperature compensation based on the second-order correction data or the fourth-order correction data may be omitted. Order of polynomial approximation may be any order. For example, polynomial approximation of an order higher than the fifth order may be performed.

The reference voltage generation circuit 60 for temperature compensation generates and outputs a reference voltage for temperature compensation to the temperature compensation circuit 40. The reference voltage generated by the reference voltage generation circuit 60 is the reference voltage VRC, described later, or the reference voltage input into one of the first transistor or the second transistor of the differential pair of the differential pair circuit. In this case, the temperature detection voltage VTS is input into the other transistor. For example, the reference voltage generation circuit 60 includes a reference circuit that generates a voltage VRF such as a BGR voltage. BGR is the abbreviation for bandgap reference. The reference voltage generation circuit 60 generates the reference voltage based on the voltage VRF generated by the reference circuit. In this case, the reference voltage generation circuit 60 may include a regulator and generate the reference voltage based on a voltage generated by the regulator based on the voltage VRF. For example, the regulator regulates the power supply voltage VDD based on the voltage VRF, and the reference voltage generation circuit 60 generates the reference voltage based on the voltage generated by the regulator. For example, the reference voltage generation circuit 60 generates the reference voltage using the voltage VRF generated by the reference circuit or the voltage generated by the regulator based on the voltage VRF as a reference power supply voltage. For example, the reference voltage generation circuit 60 generates the reference voltage by performing voltage division on the reference power supply voltage via a voltage generation circuit configured with a resistor circuit or the like. In this case, a plurality of reference voltages may be generated by changing a resistor division ratio in the voltage generation circuit and be supplied to the temperature compensation circuit 40.

The power supply circuit 90 is supplied with, for example, the external power supply voltage VDD or the ground voltage GND and supplies various power supply voltages for internal circuits of the circuit device 20 to the internal circuits. For example, the power supply circuit 90 is supplied with the power supply voltage VDD from the pad PVDD and VSS which is the ground voltage GND from the pad PGND, and supplies various power supply voltages for the internal circuits of the circuit device 20 to the internal circuits. For example, the power supply circuit 90 supplies a power supply voltage or the like obtained by regulating the power supply voltage to each circuit of the circuit device 20 such as the oscillation circuit 30, the temperature compensation circuit 40, the temperature detection circuit 50, the reference voltage generation circuit 60, and the tail current control circuit 70.

The control circuit 100 is a circuit that performs various control processes, and is implemented by, for example, a logic circuit. For example, the control circuit 100 controls the whole circuit device 20 or controls an operation sequence of the circuit device 20. In addition, the control circuit 100 performs various processes for controlling the oscillation circuit 30, controls the temperature compensation circuit 40, the temperature detection circuit 50, the reference voltage generation circuit 60, the tail current control circuit 70, the output circuit 80, or the power supply circuit 90, or controls reading or writing of information in the non-volatile memory 110. The control circuit 100 can be implemented by, for example, a circuit of an application specific integrated circuit (ASIC) via automatic place and route, such as a gate array.

The non-volatile memory 110 is a memory that maintains storage of information even when power is not supplied. For example, the non-volatile memory 110 is a memory that can maintain information and also enables writing of information even when power is not supplied. The non-volatile memory 110 stores various types of information necessary for an operation and the like of the circuit device 20. The non-volatile memory 110 can be implemented by an electrically erasable programmable read-only memory (EEPROM) or the like implemented by a floating gate avalanche injection MOS memory (FAMOS memory) or a metal-oxide-nitride-oxide-silicon memory (MONOS memory). The non-volatile memory 110 stores correction data such as the first-order correction data and the higher-order correction data used for temperature compensation of the temperature compensation circuit 40.

The output circuit 80 outputs the clock signal CK based on the oscillation signal of the oscillation circuit 30. For example, the output circuit 80 buffers and outputs the oscillation signal which is the oscillation clock signal from the oscillation circuit 30, to the pad PCK as the clock signal CK. The clock signal CK is externally output via a clock output terminal TCK of the oscillator 4. For example, the output circuit 80 outputs the clock signal CK in a single-ended CMOS signal form. The output circuit 80 may output the clock signal CK in a signal form other than CMOS. Alternatively, a clock signal generation circuit such as a PLL circuit that generates the clock signal CK having a frequency obtained by multiplying the frequency of the oscillation signal may be provided on a rear stage of the oscillation circuit 30, and the output circuit 80 may buffer and output the clock signal CK generated by the clock signal generation circuit.

In FIG. 2, the higher-order correction circuit 44 includes a first compensation circuit 47 and a second compensation circuit 48. The tail current control circuit 70 includes a first tail current control circuit 71 and a second tail current control circuit 72. The first compensation circuit 47 is a circuit that performs temperature compensation of a low-temperature side, and the second compensation circuit 48 is a circuit that performs temperature compensation of a high-temperature side. The low-temperature side is, for example, a first temperature range, and the high-temperature side is, for example, a second temperature range. Specifically, the first compensation circuit 47 includes a differential pair circuit DPL for the low-temperature side as the differential pair circuit DP, and the differential pair circuit DPL generates a current for temperature compensation of the low-temperature side (first temperature range). The second compensation circuit 48 includes a differential pair circuit DPH for the high-temperature side as the differential pair circuit DP, and the differential pair circuit DPH generates a current for temperature compensation of the high-temperature side (second temperature range). The differential pair circuit DPL is a first differential pair circuit, and the differential pair circuit DPH is a second differential pair circuit. The first compensation circuit 47 can include a plurality of differential pair circuits DPL, and the second compensation circuit 48 can also include a plurality of differential pair circuits DPH.

The first tail current control circuit 71 outputs a bias voltage VBL for controlling the tail current of the differential pair circuit DPL of the low-temperature side to the differential pair circuit DPL. The second tail current control circuit 72 outputs a bias voltage VBH for controlling the tail current of the differential pair circuit DPH of the high-temperature side to the differential pair circuit DPH. The temperature detection voltage VTS from the temperature detection circuit 50 and the reference voltage from the reference voltage generation circuit 60 are input into the differential pair circuit DPL. The differential pair circuit DPL generates the current for higher-order compensation of the low-temperature side by controlling the tail current via the bias voltage VBL. The temperature detection voltage VTS from the temperature detection circuit 50 and the reference voltage from the reference voltage generation circuit 60 are input into the differential pair circuit DPH. The differential pair circuit DPH generates the current for higher-order compensation of the high-temperature side by controlling the tail current via the bias voltage VBH. The temperature detection voltage VTS input into the differential pair circuit DPL and the temperature detection voltage VTS input into the differential pair circuit DPH may have different polarities of the temperature characteristic.

Specifically, the first tail current control circuit 71 of the low-temperature side controls a first tail current which is the tail current of the differential pair circuit DPL, to reach the minimum current value at the temperature of the inflection point of the temperature compensation voltage VCP and to have a current value that increases as the temperature decreases from the temperature of the inflection point. For example, the first tail current is controlled to have a current value that monotonically increases as the temperature decreases from the temperature of the inflection point. In this case, the first tail current control circuit 71 controls the first tail current to reach the minimum current value when the temperature is higher than the temperature of the inflection point. That is, the first tail current is controlled to have a current value that increases when the temperature is lower than the temperature of the inflection point, and to reach the minimum current value when the temperature is higher than the temperature of the inflection point.

The second tail current control circuit 72 of the high-temperature side controls a second tail current which is the tail current of the differential pair circuit DPH, to reach the minimum current value at the temperature of the inflection point of the temperature compensation voltage VCP and to have a current value that increases as the temperature increases from the temperature of the inflection point. For example, the second tail current is controlled to have a current value that monotonically increases as the temperature increases from the temperature of the inflection point. In this case, the second tail current control circuit 72 controls the second tail current to reach the minimum current value when the temperature is lower than the temperature of the inflection point. That is, the second tail current is controlled to have a current value that increases when the temperature is higher than the temperature of the inflection point, and to reach the minimum current value when the temperature is lower than the temperature of the inflection point.

In this case, the current value of the first tail current of the differential pair circuit DPL controlled by the first tail current control circuit 71 increases with a first-order characteristic as the temperature decreases from the temperature of the inflection point. That is, the current value of the first tail current monotonically increases with the first-order characteristic on the low-temperature side with respect to the temperature of the inflection point. The current value of the second tail current of the differential pair circuit DPH controlled by the second tail current control circuit 72 increases with the first-order characteristic as the temperature increases from the temperature of the inflection point. That is, the current value of the second tail current monotonically increases with the first-order characteristic on the high-temperature side with respect to the temperature of the inflection point.

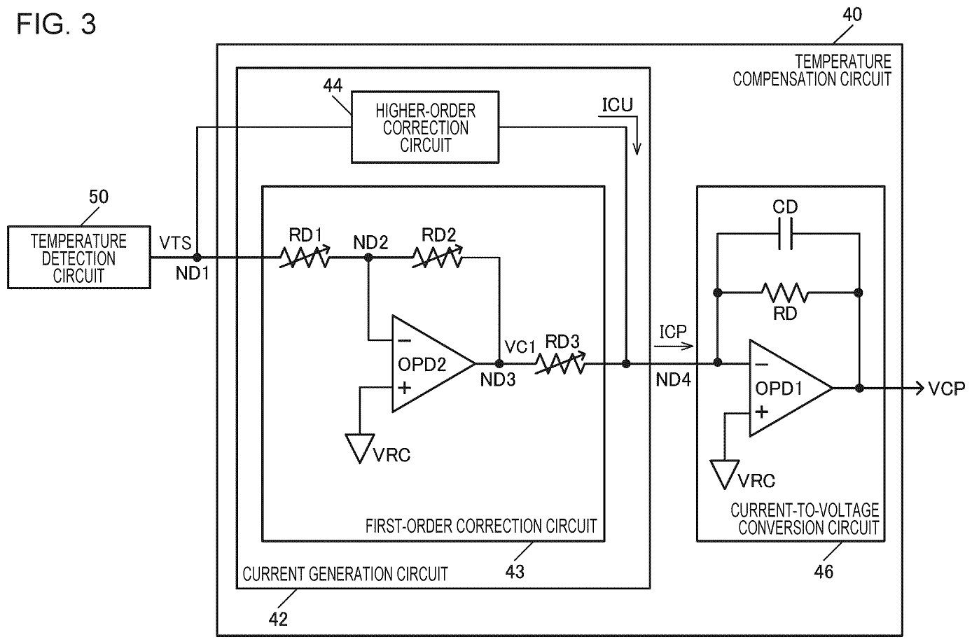

FIG. 3 shows a configuration example of the temperature compensation circuit 40. The temperature compensation circuit 40 is not limited to the configuration in FIG. 3, and various modifications such as omitting some of the components, adding other components, or replacing some of the components with other components can be made.

The temperature compensation circuit 40 is a circuit that outputs the temperature compensation voltage VCP via polynomial approximation which takes the temperature as a variable. The temperature compensation circuit 40 includes a current generation circuit 42 and a current-to-voltage conversion circuit 46. The current generation circuit 42 generates a temperature compensation current ICP based on a temperature detection result of the temperature detection circuit 50. For example, the current generation circuit 42 generates the temperature compensation current ICP for temperature compensation of the frequency-temperature characteristic of the resonator 10 based on the temperature detection voltage VTS which is the temperature detection result. The temperature compensation current ICP is also called a functional current. The current-to-voltage conversion circuit 46 converts the temperature compensation current ICP from the current generation circuit 42 into a voltage and outputs the temperature compensation voltage VCP. Specifically, the current-to-voltage conversion circuit 46 outputs the temperature compensation voltage VCP via an operational amplifier OPD1.

The current generation circuit 42 includes a first-order correction circuit 43 and the higher-order correction circuit 44. The first-order correction circuit 43 and the higher-order correction circuit 44 are also called a first-order compensation circuit and a higher-order compensation circuit. The first-order correction circuit 43 outputs a first-order compensation current that approximates a first-order function, based on the temperature detection voltage VTS. For example, the first-order correction circuit 43 outputs the first-order compensation current based on the first-order correction data corresponding to the first-order coefficient of the polynomial in the polynomial approximation. The higher-order correction circuit 44 outputs a higher-order compensation current ICU that approximates a higher-order function, to the current-to-voltage conversion circuit 46 based on the temperature detection voltage VTS. For example, the higher-order correction circuit 44 outputs the higher-order compensation current ICU based on the higher-order correction data corresponding to the higher-order coefficient of the polynomial in the polynomial approximation. A current obtained by adding the higher-order compensation current ICU and the first-order compensation current of the first-order correction circuit 43 is input into the current-to-voltage conversion circuit 46 as the temperature compensation current ICP.

As shown in FIG. 3, the first-order correction circuit 43 includes an operational amplifier OPD2 and resistors RD1 and RD2. The first-order correction circuit 43 can also include a resistor RD3 having a variable resistance value. The reference voltage VRC is input into a non-inverting input terminal of the operational amplifier OPD2. The resistor RD1 is provided between a node ND1 into which the temperature detection voltage VTS is input, and a node ND2 of an inverting input terminal of the operational amplifier OPD2. The resistor RD2 is provided between the node ND2 and a node ND3 of an output terminal of the operational amplifier OPD2. The resistor RD3 is provided between the node ND3 and an output node ND4 of the current generation circuit 42.

The current-to-voltage conversion circuit 46 outputs the temperature compensation voltage VCP by performing current-to-voltage conversion on the temperature compensation current ICP which is the current obtained by adding the first-order compensation current and the higher-order compensation current ICU. Accordingly, the temperature compensation voltage VCP that approximates a polynomial function is generated. Specifically, the current-to-voltage conversion circuit 46 includes the operational amplifier OPD1 and a resistor RD for feedback. The reference voltage VRC is input into a non-inverting input terminal of the operational amplifier OPD1, and the output node ND4 of the current generation circuit 42 is coupled to an inverting input terminal of the operational amplifier OPD1. The resistor RD is provided between an output terminal of the operational amplifier OPD1 and the inverting input terminal of the operational amplifier OPD1. While a capacitor CD for phase compensation is provided between the output terminal and the inverting input terminal of the operational amplifier OPD1 in FIG. 3, it may be configured not to provide the capacitor CD.

The temperature compensation circuit 40 in FIG. 3 includes the first-order correction circuit 43 and the higher-order correction circuit 44 into which the temperature detection voltage VTS is input, the current generation circuit 42 that generates the temperature compensation current ICP via the first-order correction circuit 43 and the higher-order correction circuit 44, and the current-to-voltage conversion circuit 46 that converts the temperature compensation current ICP into a voltage and outputs the temperature compensation voltage VCP. According to the temperature compensation circuit 40 having such a configuration, the temperature compensation current ICP which is the functional current generated by the current generation circuit 42 based on the temperature detection voltage VTS can be converted into a voltage and output as the temperature compensation voltage VCP by the current-to-voltage conversion circuit 46.

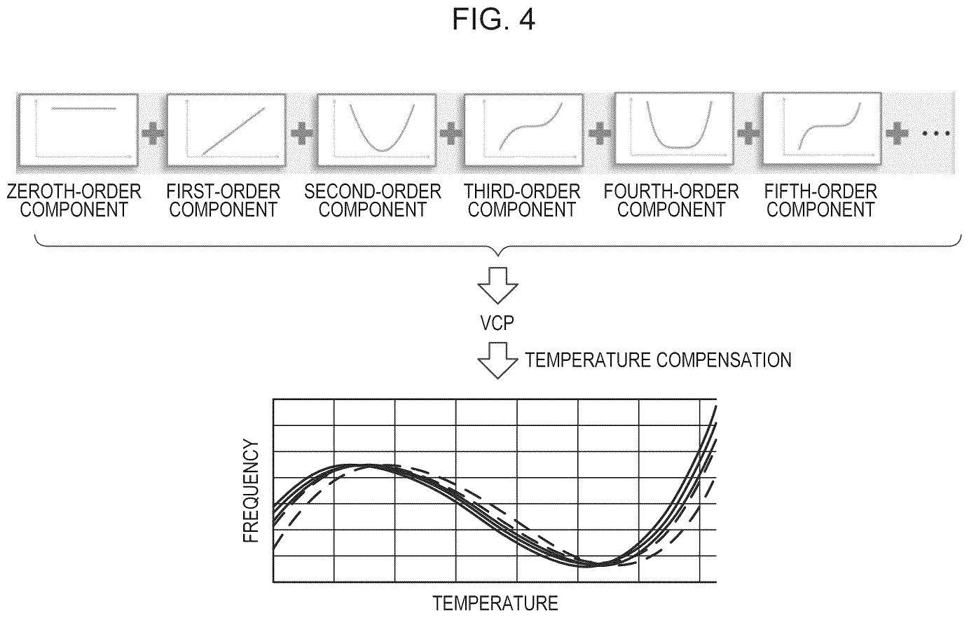

FIG. 4 is a descriptive diagram of temperature compensation. A zeroth-order component, a first-order component, a second-order component, a third-order component, a fourth-order component, and a fifth-order component have characteristics of a zeroth-order function, a first-order function, a second-order function, a third-order function, a fourth-order function, and a fifth-order function, respectively, with respect to the temperature. Temperature compensation for correcting the first-order component is performed by the first-order correction circuit 43 in FIG. 3, and temperature compensation for correcting the second-order component, the third-order component, the fourth-order component, and the fifth-order component is performed by the higher-order correction circuit 44. Correction of the second-order component and the fourth-order component may be omitted. By changing the capacitance of the variable capacitance circuit 32 based on the temperature compensation voltage VCP generated by temperature compensation in FIG. 4, a change in the oscillation frequency of the resonator 10 caused by the temperature can be canceled out, and a constant oscillation frequency can be obtained in response to a change in the temperature. In this case, process variation occurs in the temperature characteristic of the oscillation frequency of the resonator 10. Thus, for example, when a product is shipped, a clock frequency of the oscillator 4 is monitored, and appropriate correction data based on a monitoring result is written into the non-volatile memory 110 of the circuit device 20 to perform temperature compensation based on the correction data.

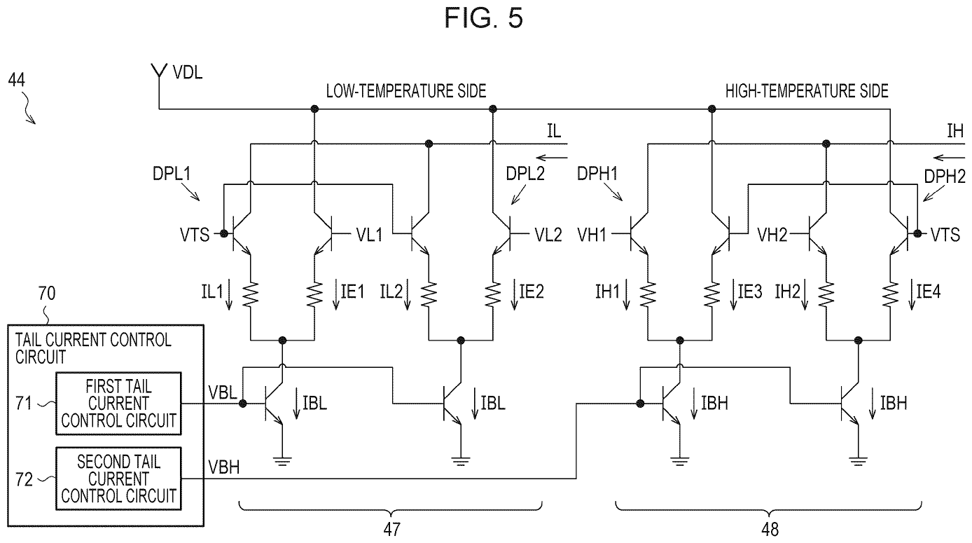

FIG. 5 is a configuration example of the first compensation circuit 47 and the second compensation circuit 48 provided in the higher-order correction circuit 44. The first compensation circuit 47 performs temperature compensation in the first temperature range which is the temperature range of the low-temperature side, and the second compensation circuit 48 performs temperature compensation in the second temperature range which is the temperature range of the high-temperature side. The first compensation circuit 47 includes a plurality of differential pair circuits DPL1 and DPL2 of the low-temperature side. The second compensation circuit 48 includes a plurality of differential pair circuits DPH1 and DPH2 of the high-temperature side.

The first tail current control circuit 71 of the tail current control circuit 70 outputs the bias voltage VBL to the differential pair circuits DPL1 and DPL2 of the low-temperature side. Accordingly, a tail current IBL flows through the differential pair circuits DPL1 and DPL2. The second tail current control circuit 72 of the tail current control circuit 70 outputs the bias voltage VBH to the differential pair circuits DPH1 and DPH2 of the high-temperature side. Accordingly, a tail current IBH flows through the differential pair circuits DPH1 and DPH2.

Each of the differential pair circuits DPL1, DPL2, DPH1, and DPH2 includes a first bipolar transistor and a second bipolar transistor as a differential pair. The temperature detection voltage VTS is input into a base of the first bipolar transistor, and any of VL1, VL2, VH1, or VH2 which is the reference voltage is input into a base of the second bipolar transistor. These reference voltages are generated by the reference voltage generation circuit 60 in FIG. 2. In addition, each differential pair circuit includes a third bipolar transistor as a transistor of a current source. The bias voltage VBL from the first tail current control circuit 71 or the bias voltage VBH from the second tail current control circuit 72 is input into a base of the third bipolar transistor.

The first compensation circuit 47 generates a current IL=IL1+IL2 for temperature compensation in the temperature range of the low-temperature side. The second compensation circuit 48 generates a current IH=IH1+IH2 for temperature compensation in the temperature range of the high-temperature side. The tail currents IBL=IL1+IE1 and IBL=IL2+IE2 flow through the differential pair circuits DPL1 and DPL2 of the first compensation circuit 47. The tail currents IBH=IH1+IE3 and IBH=IH2+IE4 flow through the differential pair circuits DPH1 and DPH2 of the second compensation circuit 48.

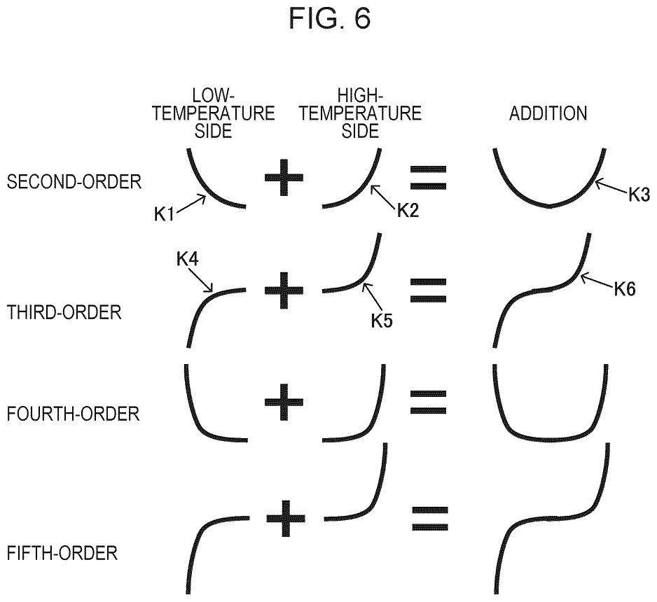

In the temperature range of the low-temperature side, the current IH=IH1+IH2 decreases and reaches, for example, 0 while the current IL=IL1+IL2 increases. On the other hand, in the temperature range of the high-temperature side, the current IL=IL1+IL2 decreases and reaches, for example, 0 while the current IH=IH1+IH2 increases. The higher-order correction circuit 44 having such a configuration can be used to generate the higher-order compensation current of a second order, a third order, a fourth order, a fifth order, or the like as shown in FIG. 6. For example, a characteristic shown by K1 in FIG. 6 is set for the current IL flowing through the first compensation circuit 47 in the temperature range of the low-temperature side, and a characteristic shown by K2 is set for the current IH flowing through the second compensation circuit 48 in the temperature range of the high-temperature side. Accordingly, the higher-order compensation current of the second order as shown by K3 can be generated. A characteristic shown by K4 in FIG. 6 is set for the current IL flowing through the first compensation circuit 47 in the temperature range of the low-temperature side, and a characteristic shown by K5 is set for the current IH flowing through the second compensation circuit 48 in the temperature range of the high-temperature side. Accordingly, the higher-order compensation current of the third order as shown by K6 can be generated. The same method can be used to generate the higher-order compensation current of the fourth order or the fifth order.

While FIG. 5 shows providing two differential pair circuits in each compensation circuit of the first compensation circuit 47 and the second compensation circuit 48, the number of differential pair circuits included in each compensation circuit is not limited to this, and the number of differential pair circuits may be three or more. In addition, in the configuration in FIG. 5, different polarities are set for the polarity of the temperature characteristic of the temperature detection voltage VTS used for the first compensation circuit 47 of the low-temperature side and the polarity of the temperature characteristic of the temperature detection voltage VTS used for the second compensation circuit 48 of the high-temperature side. For example, when the temperature detection voltage VTS having a negative temperature characteristic is used in the first compensation circuit 47 of the low-temperature side, the temperature detection voltage VTS having a positive temperature characteristic may be used in the second compensation circuit 48 of the high-temperature side.

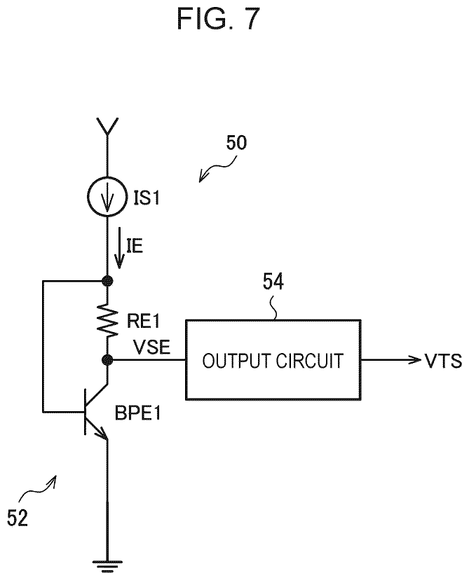

FIG. 7 shows a configuration example of the temperature detection circuit 50. The temperature detection circuit 50 includes a temperature sensor 52 and an output circuit 54. The temperature sensor 52 includes a constant current source IS1, a bipolar transistor BPE1, and a resistor RE1. The constant current source IS1, the resistor RE1, and the bipolar transistor BPE1 are provided in series between a power supply node of a high-potential side and a power supply node of a low-potential side. Specifically, a coupling node between the constant current source IS1 and one end of the resistor RE1 is coupled to a base of the bipolar transistor BPE1, and the other end of the resistor RE1 is coupled to a collector of the bipolar transistor BPE1. An emitter of the bipolar transistor BPE1 is coupled to the power supply node of the low-potential side. The output circuit 54 outputs the temperature detection voltage VTS based on a sensor voltage VSE from the temperature sensor 52.

In FIG. 7, a current flowing from the constant current source IS1 is denoted by IE. A resistance value of the resistor RE1 is denoted by the same reference sign RE1. A base-emitter voltage of the bipolar transistor BPE1 is denoted by VBE1. The sensor voltage is represented by VSE=VBE1−IE×RE1. The base-emitter voltage VBE1 of the bipolar transistor BPE1 has a negative temperature characteristic. Thus, the temperature detection voltage VTS generated based on the sensor voltage VSE also has a negative temperature characteristic.

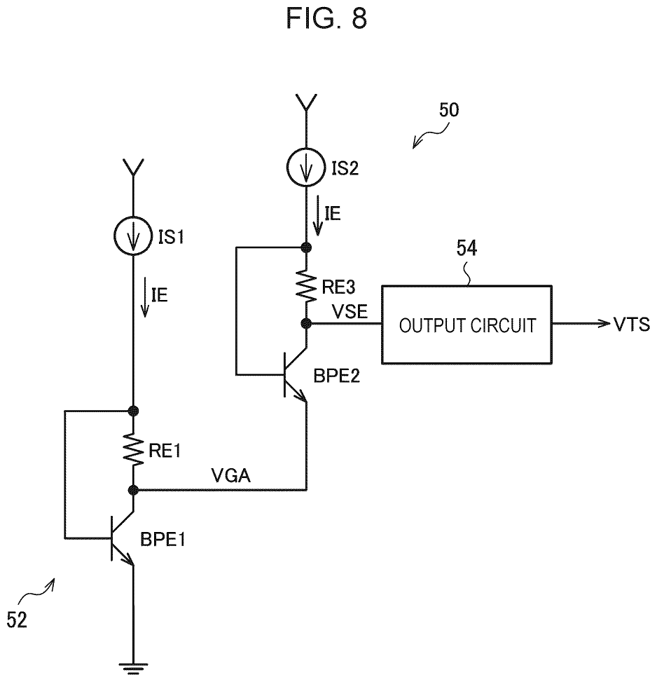

FIG. 8 shows another configuration example of the temperature detection circuit 50. The temperature sensor 52 of the temperature detection circuit 50 in FIG. 8 includes constant current sources IS1 and IS2, bipolar transistors BPE1 and BPE2, and resistors RE1 and RE3. A coupling configuration of the constant current source IS1, the bipolar transistor BPE1, and the resistor RE1 is the same as the configuration example in FIG. 7. The constant current source IS2, the resistor RE3, and the bipolar transistor BPE2 are provided in series between the power supply node of the high-potential side and a node of the collector of the bipolar transistor BPE1. Specifically, a coupling node between the constant current source IS2 and one end of the resistor RE3 is coupled to a base of the bipolar transistor BPE2, and the other end of the resistor RE3 is coupled to a collector of the bipolar transistor BPE2. An emitter of the bipolar transistor BPE2 is coupled to the collector of the bipolar transistor BPE1.

In FIG. 8, voltages between the collectors of the bipolar transistors BPE1 and BPE2 are denoted by VGA and VSE respectively. Currents flowing through the constant current sources IS1 and IS2 are denoted by IE. Resistance values of the resistors RE1 and RE3 are denoted by reference signs RE1 and RE3 respectively. Base-emitter voltages of the bipolar transistors BPE1 and BPE2 are denoted by VBE1 and VBE2. The sensor voltage is represented by VSE=VBE2−IE×RE3+VGA=VBE1+VBE2−IE×(RE1+RE3). The base-emitter voltages VBE1 and VBE2 of the bipolar transistors BPE1 and BPE2 have negative temperature characteristics. Thus, the temperature detection voltage VTS generated based on the sensor voltage VSE also has a negative temperature characteristic.

In the configuration example in FIG. 8, the bipolar transistors BPE1 and BPE2 in two stages are provided. Thus, two base-emitter voltages VBE1 and VBE2 are added. Accordingly, compared to the configuration example in FIG. 7, a slope of the temperature detection voltage VTS with respect to the temperature can be increased, and the temperature detection voltage VTS having high sensitivity to the temperature can be generated.

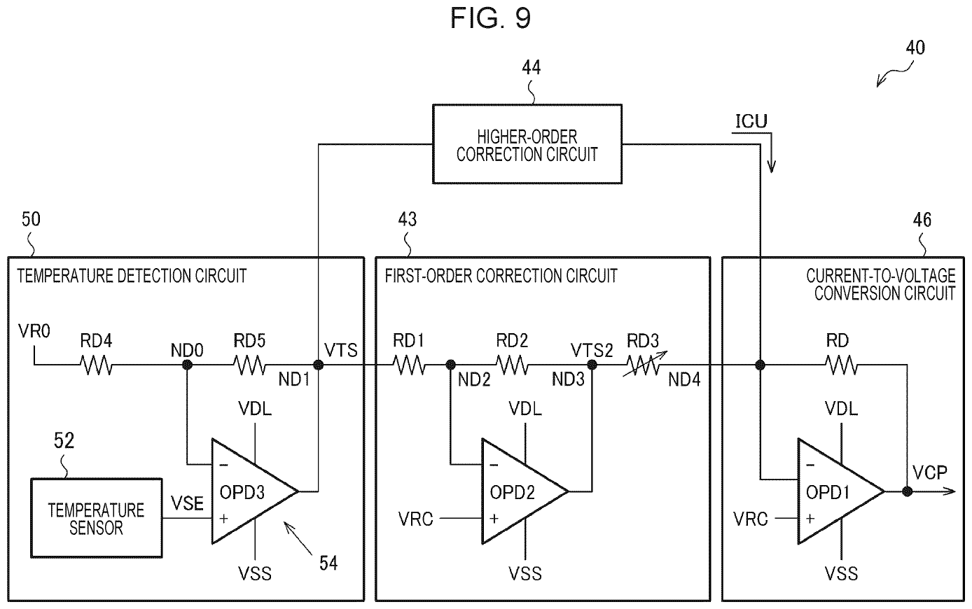

FIG. 9 shows a specific configuration example of the temperature detection circuit 50 and the temperature compensation circuit 40. The temperature compensation circuit 40 has the same configuration as that in FIG. 3 and thus, will not be described in detail. FIG. 9 shows a configuration example of the output circuit 54 provided in the temperature detection circuit 50. The output circuit 54 includes an operational amplifier OPD3 and resistors RD4 and RD5.

The sensor voltage VSE from the temperature sensor 52 is input into a non-inverting input terminal of the operational amplifier OPD3. The resistor RD4 is provided between an input node of a reference voltage VRO for zeroth-order correction which is offset adjustment, and a node ND0 of an inverting input terminal of the operational amplifier OPD3. The resistor RD5 is provided between the node ND0 and the node ND1 of an output terminal of the operational amplifier OPD3. In the present embodiment, a resistor and its resistance value are denoted by the same reference sign. For example, resistance values of the resistors RD, RD1, RD2, RD3, RD4, and RD5 are also denoted by RD, RD1, RD2, RD3, RD4, and RD5. The temperature detection voltage VTS is represented by Equation (1).

$$VTS = ( 1 + \frac{RD 5}{RD 4} ) VSE - \frac{RD 5}{RD 4} VR 0 \qquad ( 1 )$$

A voltage VTS2 output by the operational amplifier OPD2 of the first-order correction circuit 43 is represented by Equation (2). The voltage VTS2 has, for example, a positive temperature characteristic and thus, can be referred to as a temperature detection voltage.

$$VTS 2 = - \frac{RD 2}{RD 1} VTS + ( 1 + \frac{RD 2}{RD 1} ) VRC \qquad ( 2 )$$

When the higher-order compensation current from the higher-order correction circuit 44 is denoted by ICU, the temperature compensation voltage VCP is represented by Equation (3).

$$VCP = - \frac{RD}{RD 3} VTS 2 + ( 1 + \frac{RD}{RD 3} ) VRC + ICU \cdot RD \qquad ( 3 )$$

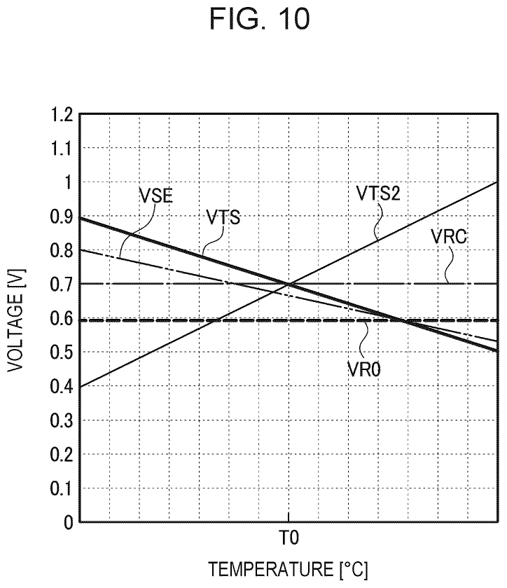

FIG. 10 shows temperature characteristics of the sensor voltage VSE, the temperature detection voltage VTS, the voltage VTS2, and the reference voltage VRC. As shown in FIG. 10, the temperature detection voltage VTS and the sensor voltage VSE have negative temperature characteristics, and the voltage VTS2 has a positive temperature characteristic. The temperature detection voltage VTS, the voltage VTS2, and the reference voltage VRC have characteristics that intersect with each other at TO which is the temperature of the inflection point.

### 2. Control of Tail Current of Differential Pair Circuit

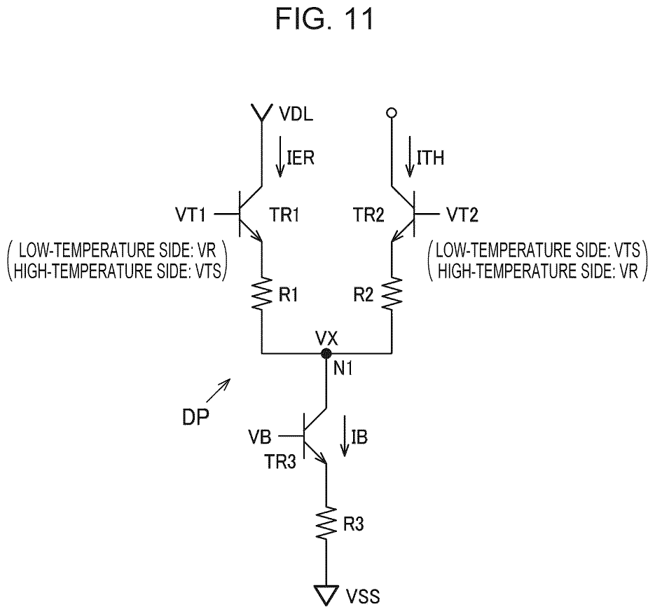

FIG. 11 shows a configuration example of the differential pair circuit DP. The differential pair circuit DP corresponds to the differential pair circuits DPL, DPH, DPL1, DPL2, DPH1, and DPH2 in FIGS. 2 and 5. In the present embodiment, all of the differential pair circuits DPL, DPL1, and DPL2 of the low-temperature side and the differential pair circuits DPH, DPH1, and DPH2 of the high-temperature side will be collectively referred to as the differential pair circuit DP as appropriate for simplification of description.

As shown in FIG. 11, the differential pair circuit DP includes a bipolar transistor TR1 and a resistor R1 provided in series between a node of VDL and a node N1. The differential pair circuit DP also includes a bipolar transistor TR2 and a resistor R2 provided in series between the node of VDL and the node N1, in parallel with TR1 and R1. The n-p-n bipolar transistors TR1 and TR2 are transistors constituting a differential pair. The differential pair circuit DP also includes a bipolar transistor TR3 and a resistor R3 provided in series between the node N1 and a node of VSS.

A voltage VT1 is input into a base of the bipolar transistor TR1 of the differential pair, and a voltage VT2 is input into a base of the bipolar transistor TR2 of the differential pair. Accordingly, a current IER flows through the bipolar transistor TR1, and a current ITH flows through the bipolar transistor TR2. In this case, in the differential pair circuit DP (DPL, DPL1, DPL2) of the low-temperature side, a reference voltage VR is input into the base of the bipolar transistor TR1, and the temperature detection voltage VTS is input into the base of the bipolar transistor TR2. On the other hand, in the differential pair circuit DP (DPH, DPH1, DPH2) of the high-temperature side, the temperature detection voltage VTS is input into the base of the bipolar transistor TR1, and the reference voltage VR is input into the base of the bipolar transistor TR2. In this case, for example, different polarities are set for the polarity of the temperature characteristic of the temperature detection voltage VTS used for the differential pair circuit DP of the low-temperature side and the polarity of the temperature detection voltage VTS used for the differential pair circuit DP of the high-temperature side.

The bias voltage VB is input into a base of the bipolar transistor TR3 that is a current source. Accordingly, a tail current IB flows through the bipolar transistor TR3. For example, as shown in FIG. 5, the tail current IBL flows through the bipolar transistors TR3 of the differential pair circuits DPL1 and DPL2 of the low-temperature side because of the bias voltage VBL from the first tail current control circuit 71. The tail current IBH flows through the bipolar transistors TR3 of the differential pair circuits DPH1 and DPH2 of the high-temperature side because of the bias voltage VBH from the second tail current control circuit 72.

In FIG. 11, the relationship of Equation (4) is established between the tail current IB flowing through the bipolar transistor TR3 and the currents IER and ITH flowing through the bipolar transistors TR1 and TR2.

IB=ITH+IER (4)

When a base-emitter voltage of a bipolar transistor is denoted by VBE, and a saturation current is denoted by IS, a collector current IC of the bipolar transistor is represented by Equation (5).

$$IC = IS \cdot exp ( \frac{VBE}{VT} ) \qquad ( 5 )$$

In Equation (5), VT=kT/q is established, where k is the Boltzmann constant, T is the temperature, and q is electric charge of an electron. When a voltage of the node N1 is denoted by VX, a base-emitter voltage of the bipolar transistor TR1 is VBE=VT1−VX, and a base-emitter voltage of the bipolar transistor TR2 is VBE=VT2−VX. Accordingly, the currents ITH and IER flowing through the bipolar transistors TR2 and TR1 are represented by Equations (6) and (7).

$$ITH = IS \cdot exp ( \frac{VT 2 - VX}{VT} ) \qquad ( 6 )$$

$$IER = IS \cdot exp ( \frac{VT 1 - VX}{VT} ) \qquad ( 7 )$$

According to Equations (6) and (7), IER/ITH is represented by Equation (8).

$$\frac{IER}{ITH} = exp ( \frac{VT 1 - VT 2}{VT} ) \qquad ( 8 )$$

Accordingly, from Equations (4) and (8), the current ITH for temperature compensation flowing through the bipolar transistor TR2 is represented by Equation (9).

$$ITH = \frac{IB}{1 + exp ( \frac{VT 1 - VT 2}{VT} )} \qquad ( 9 )$$

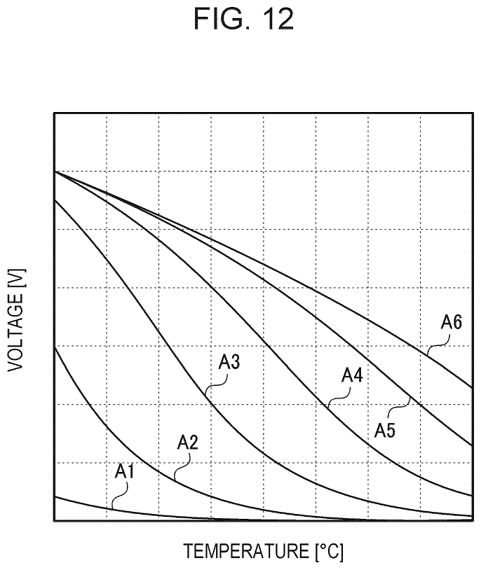

FIG. 12 is a temperature characteristic example of the current ITH for temperature compensation flowing through the differential pair circuit DP of the low-temperature side. In the differential pair circuit DP of the low-temperature side, VT1=VR and VT2=VTS are input into the bases of the bipolar transistors TR1 and TR2, respectively. The current ITH corresponds to the current IL in FIG. 5, and the reference voltage VR corresponds to the voltages VL1 and VL2. By setting the voltage VT1=VR, temperature characteristics of A1, A2, A3, A4, A5, and A6 in FIG. 12 are set. For example, A1, A2, A3, A4, A5, and A6 are temperature characteristics for VT1=VR=0.95 V, 0.90 V, 0.85 V, 0.80 V, 0.75 V, and 0.70 V, respectively. For example, as VT1=VR decreases, the temperature characteristic changes as shown by A1, A2, A3, A4, A5, and A6. Accordingly, various temperature characteristics can be implemented by setting the reference voltage VR, and a desired temperature characteristic can be implemented by combining these temperature characteristics.

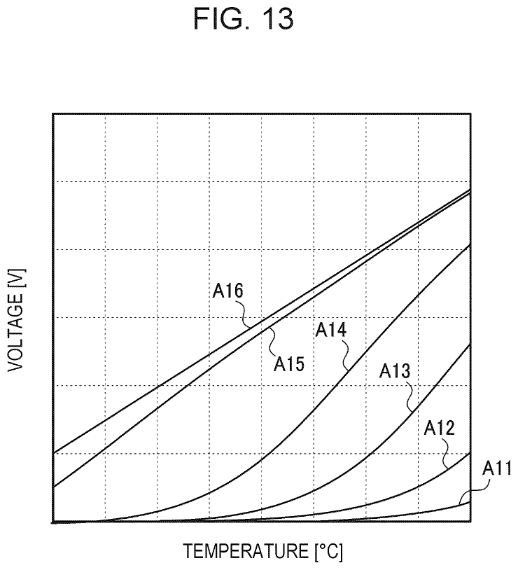

FIG. 13 is a temperature characteristic example of the current ITH for temperature compensation flowing through the differential pair circuit DP of the high-temperature side. In the differential pair circuit DP of the high-temperature side, VT1=VTS and VT2=VR are input into the bases of the bipolar transistors TR1 and TR2, respectively. That is, a voltage input opposite to that of the low-temperature side is provided. The current ITH corresponds to the current IH in FIG. 5, and the reference voltage VR corresponds to the voltages VH1 and VH2. By setting the voltage VT2=VR, temperature characteristics of A11, A12, A13, A14, A15, and A16 in FIG. 13 are set. For example, as VT2=VR increases, the temperature characteristic changes as shown by A11, A12, A13, A14, A15, and A16. Accordingly, even on the high-temperature side, various temperature characteristics can be implemented by setting the reference voltage VR, and a desired temperature characteristic can be implemented by combining these temperature characteristics. Accordingly, the higher-order compensation current having the desired temperature characteristic can be generated by the current ITH=IH for temperature compensation of the low-temperature side and the current ITH=IL for temperature compensation of the high-temperature side.

In recent years, there has been demand for reduction in the power supply voltage VDD. Reduction in the power supply voltage VDD can implement reduction in power consumption and the like of the circuit device 20 and the oscillator 4.

However, as reduction in the power supply voltage VDD progresses, an issue arises in that the gain of the temperature characteristic of the temperature detection voltage VTS input into the differential pair circuit DP decreases, and it is difficult to generate appropriate higher-order compensation current via only the transistors of the differential pair of the differential pair circuit DP.

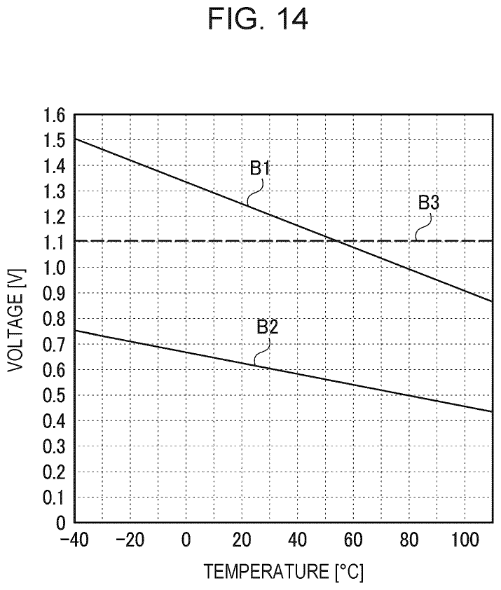

For example, in FIG. 14, B1 is the temperature characteristic of the temperature detection voltage VTS of the temperature detection circuit 50 in FIG. 8, and B2 is the temperature characteristic of the temperature detection voltage VTS of the temperature detection circuit 50 in FIG. 7. B3 shows a lower limit of the reduced power supply voltage. According to a configuration in which bipolar transistors are provided in two stages as in FIG. 8, the gain of the temperature characteristic can be increased as shown by B1 in FIG. 8. Here, the gain of the temperature characteristic corresponds to a slope of a first-order temperature characteristic. However, when the power supply voltage is reduced as shown by B3, it is difficult to adopt the temperature detection circuit 50 having the configuration of two-staged bipolar transistors as in FIG. 8. When the temperature detection circuit 50 having a configuration of one-staged bipolar transistor as in FIG. 7 is used to deal with reduction in the power supply voltage, the slope of the first-order characteristic which is the gain of the temperature characteristic of the temperature detection voltage VTS decreases as shown by B2.

In the related art, the tail current IB that is a constant current flows through the differential pair circuit DP. However, when the gain of the temperature characteristic of the temperature detection voltage VTS decreases, an issue arises in that it is difficult to generate an appropriate higher-order compensation current via the tail current IB that is a constant current.

The current ITH for temperature compensation generated by the differential pair circuit DP is represented by Equation (9). When ΔVT=VT1−VT2 in Equation (9) decreases because of an effect of reduction in the power supply voltage and the like, it is difficult to decrease the current ITH for temperature compensation near the temperature of the inflection point (for example, 25° C. to 35° C.).

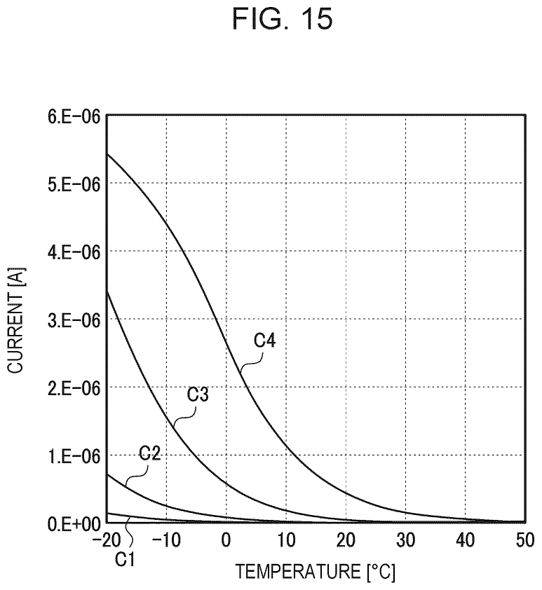

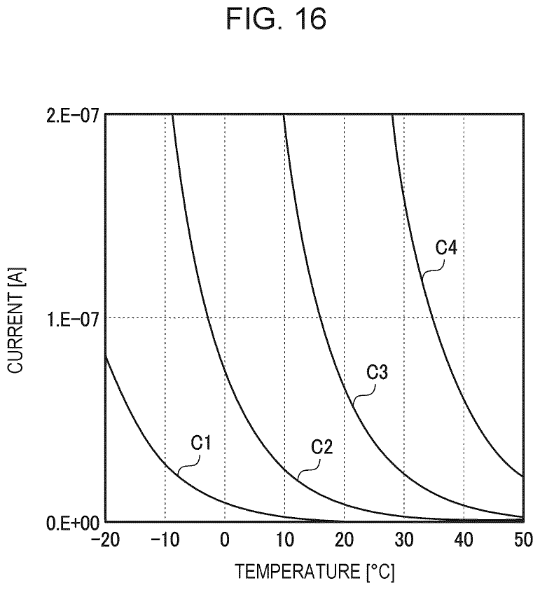

For example, C1, C2, C3, and C4 in FIG. 15 are temperature characteristic examples of the current ITH for temperature compensation, and FIG. 16 is a diagram in which the temperature characteristics in FIG. 15 are enlarged in a vertical axis direction which is an axial direction of the current. C1, C2, C3, and C4 are temperature characteristics when ΔVT=VT1−VT2 is 0.25 V, 0.2 V, 0.15 V, and 0.1 V, respectively. As shown by C2, C3, and C4 in FIG. 16, when ΔVT=VT1−VT2 is small like 0.2 V, 0.15 V, and 0.1 V, it is difficult to set the current ITH to zero near the temperature of the inflection point.

For example, the reference voltage VRC input into the non-inverting input terminals of the operational amplifiers OPD1 and OPD2 of the temperature compensation circuit 40 in FIG. 3 is 0.7 V at the temperature of the inflection point. As shown in FIG. 10, at the temperature TO of the inflection point, the temperature detection voltage VTS is equal to the reference voltage VRC, and VT2=VTS in FIG. 11 is 0.7 V. The reference voltage VR is generated by the reference voltage generation circuit 60 in FIG. 2 via, for example, a bandgap reference circuit based on the power supply voltage of which a lower limit voltage is, for example, 1.0 V to 1.1 V. Accordingly, VT1=VR in FIG. 11 is approximately 0.9 V at most. Accordingly, ΔVT=VT1−VT2 is approximately 0.2 V at most, and a temperature characteristic of the current ITH is the temperature characteristic shown by C2, C3, and C4 in FIG. 16. Accordingly, an issue arises in that the current ITH cannot be set to zero at the temperature of the inflection point. For example, for C2 in FIG. 16 in which ΔVT=0.2 V, a current of approximately 5 nA flows at a temperature of 30° C.

For example, when ΔVT=VT1−VT2 is sufficiently large, the temperature characteristic of the current ITH is the temperature characteristic shown by C1 in FIGS. 15 and 16. Thus, even in a configuration using the tail current IB that is a constant current as in the related art, the current ITH can be set to a current value close to zero at the temperature of the inflection point. However, when ΔVT=VT1−VT2 is small, the current ITH cannot be set to zero near the temperature of the inflection point. Since the higher-order compensation current is a current obtained by adding the currents ITH of the plurality of differential pair circuits DP, a current value of the higher-order compensation current at the temperature of the inflection point increases, and this hinders reduction in the power consumption.

When the current ITH cannot be decreased at the temperature of the inflection point, it is difficult to adjust the characteristic and the like of the higher-order compensation current or adjust the inflection point. For example, on the low-temperature side, the higher-order compensation current is generated by adding the currents ITH having various temperature characteristics shown by A1 to A6 in FIG. 12. On the high-temperature side, the higher-order compensation current is generated by adding the currents ITH having various temperature characteristics shown by A11 to A16 in FIG. 13. However, as shown by C2 to C4 in FIG. 15, the current ITH having a temperature characteristic in which ΔVT=VT1−VT2 is small poses an issue such as an increase in current consumption. Accordingly, only the current ITH having a temperature characteristic in which ΔVT=VT1−VT2 is large can be used, and it is not only difficult to adjust the characteristic and the like of the higher-order compensation current but also difficult to adjust the inflection point.

In FIG. 5, when the current IH of the second compensation circuit 48 flows in the temperature range of the low-temperature side in which the current IL of the first compensation circuit 47 flows, or when the current IL of the first compensation circuit 47 flows in the temperature range of the high-temperature side in which the current IH of the second compensation circuit 48 flows, unnecessary power consumption occurs. Such unnecessary power consumption occurs when the current ITH cannot be set to zero at the temperature of the inflection point, and the non-zero current ITH flows through the differential pair circuit DP of the high-temperature side in the temperature range of the low-temperature side, or the non-zero current ITH flows through the differential pair circuit DP of the low-temperature side in the temperature range of the high-temperature side.

Therefore, the present embodiment adopts a method of causing the tail current of the differential pair circuit DP of the higher-order correction circuit 44 to have a temperature characteristic and generating the higher-order compensation current via the differential pair circuit DP. That is, while the tail current of the differential pair circuit DP described above is a constant current and does not have a temperature characteristic, the tail current is caused to have a strong temperature characteristic so that its current value changes in accordance with a change in the temperature. That is, the tail current control circuit 70 controls the tail current of the differential pair circuit DP to reach the minimum current value at the temperature of the inflection point of the temperature compensation voltage VCP and to have a current value that increases in accordance with a change in the temperature from the temperature of the inflection point.

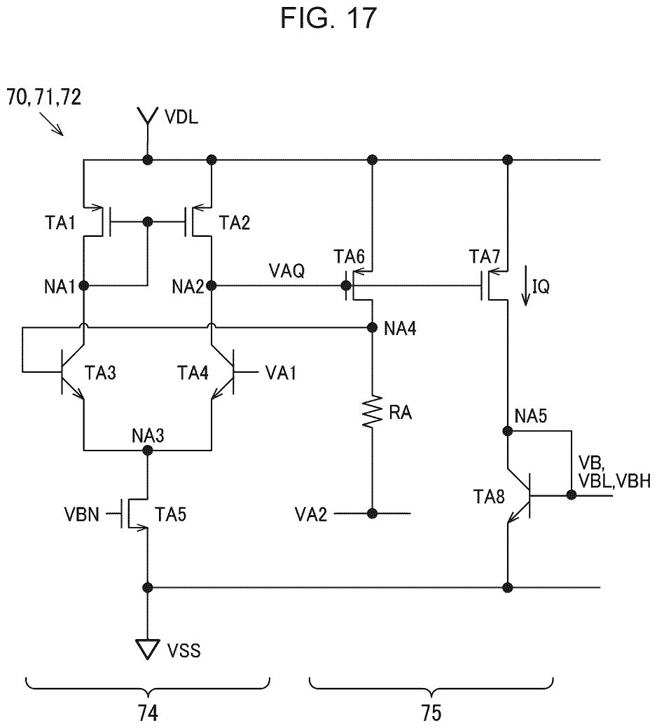

FIG. 17 shows a configuration example of the tail current control circuit 70 that controls the tail current in such a manner. While FIG. 17 is actually a configuration example of the first tail current control circuit 71 and the second tail current control circuit 72, the first tail current control circuit 71 and the second tail current control circuit 72 will be collectively described below as a configuration example of the tail current control circuit 70 for simplification of description. The tail current control circuit 70 is not limited to the configuration in FIG. 17, and various modifications such as omitting some of the components, adding other components, or replacing some of the components with other components can be made.

The tail current control circuit 70 in FIG. 17 is a transconductance amplifier that converts a difference in voltage into a current. Specifically, the tail current control circuit 70 generates a current IQ for controlling the tail current of the differential pair circuit DP by converting VA1−VA2 which is a difference in voltage between a voltage VAL and a voltage VA2 having a different temperature characteristic from the voltage VA1, into a current. The voltage VAL is a first voltage, and the voltage VA2 is a second voltage. The bias voltage VB (VBL, VBH) is generated based on the current IQ generated by the tail current control circuit 70, and the tail current of the differential pair circuit DP is controlled based on the bias voltage VB.

Specifically, the tail current control circuit 70 includes a differential unit 74 and an output unit 75. The differential unit 74 of the tail current control circuit 70 includes transistors TA1 and TA2 constituting a current mirror circuit, bipolar transistors TA3 and TA4 that are transistors of a differential pair, and a transistor TA5 that is a current source. The transistors TAL and TA2 of a P type are provided between the node of VDL and nodes NA1 and NA2, and their gates are coupled to the node NA1. The bipolar transistor TA3 of n-p-n is provided between the node NA1 and a node NA3, and its base is coupled to a node NA4 of the output unit 75. The bipolar transistor TA4 of n-p-n is provided between the node NA2 and the node NA3, and the voltage VA1 is input into its base. A modification of using N-type MOS transistors instead of the bipolar transistors TA3 and TA4 of n-p-n can also be made. The transistor TA5 of an N type is provided between the node NA3 and the node of VSS, and a bias voltage VBN is input into its gate.

The output unit 75 of the tail current control circuit 70 includes a transistor TA6 and a resistor RA provided in series between the node of VDL and the node of VA2. The output unit 75 also includes a transistor TA7 and a bipolar transistor TA8 provided in series between the node of VDL and the node of VSS. The transistor TA6 of a P type is provided between the node of VDL and the node NA4, and an output voltage VAQ of the output unit 75 is input into its gate. The resistor RA is provided between the node NA4 and an input node of the voltage VA2. The transistor TA7 of a P type is provided between the node of VDL and a node NA5. The bipolar transistor TA8 is provided between the node NA5 and the node of VSS, and its base and collector are coupled to the node NA5 of the bias voltage VB.

In the tail current control circuit 70 in FIG. 17, the differential unit 74 is virtually grounded. Accordingly, a voltage of the node NA4 to which the base of the bipolar transistor TA3 constituting the differential pair is coupled is equal to the voltage VA1 input into the base of the bipolar transistor TA4 constituting the differential pair. That is, the voltage of the node NA4 is VA1. The output voltage VAQ of the differential unit 74 is input into gates of the transistors TA6 and TA7 of the output unit 75 in common. Thus, the current IQ having the same current value as a current flowing through the transistor TA6 flows through the transistor TA7. Accordingly, when a resistance value of the resistor RA is denoted by the same reference sign RA, the current IQ represented by Equation (10) is generated when VA1>VA2 is established. On the other hand, when VA1<VA2 is established, a voltage of the node NA2 of the differential unit 74 rises, and the transistors TA6 and TA7 switch off. Thus, the current value of the current IQ is zero as in Equation (11).

$$IQ = \frac{VA 1 - VA 2}{RA} ( VA 1 > VA 2 ) \qquad ( 10 )$$

$$IQ = 0 ( VA 1 < VA 2 ) \qquad ( 11 )$$

As described above, when VA1>VA2 is established, the tail current control circuit 70 in FIG. 17 operates as a transconductance amplifier that converts (VA1−VA2) which is the difference in voltage between the voltage VA1 and the voltage VA2, into the current IQ=(VA1−VA2)/RA. The tail current corresponding to the current IQ flows through the differential pair circuit DP.

In the present embodiment, the voltages VA1 and VA2 of, for example, VA1=VTS and VA2=VTS2 are input into the tail current control circuit 70 of the low-temperature side (first tail current control circuit 71). Accordingly, in the tail current control circuit 70 of the low-temperature side, the current IQ represented by Equation (12) is generated when VA1>VA2 is established. On the other hand, when VA1<VA2 is established, the current value of the current IQ is zero as in Equation (13).

$$VA 1 = VTS , VA 2 = VTS 2 \qquad ( 12 )$$

$$IQ = \frac{VA 1 - VA 2}{RA} = \frac{VTS - VTS 2}{RA} ( VTS > VTS 2 )$$

$$IQ = 0 ( VTS < VTS 2 ) \qquad ( 13 )$$

Accordingly, the tail current corresponding to the current IQ in Equations (12) and (13) flows through the differential pair circuit DP of the low-temperature side.

On the other hand, the voltages VA1 and VA2 of, for example, VA1=VTS2 and VA2=VTS are input into the tail current control circuit 70 of the high-temperature side (second tail current control circuit 72). Accordingly, in the tail current control circuit 70 of the high-temperature side, the current IQ represented by Equation (14) is generated when VA1>VA2 is established. On the other hand, when VA1<VA2 is established, the current value of the current IQ is zero as in Equation (15).

$$VA 1 = VTS 2 , VA 2 = VTS \qquad ( 14 )$$

$$IQ = \frac{VA 1 - VA 2}{RA} = \frac{VTS 2 - VTS}{RA} ( VTS 2 > VTS )$$

$$IQ = 0 ( VTS 2 < VTS ) \qquad ( 15 )$$

Accordingly, the tail current corresponding to the current IQ in Equations (14) and (15) flows through the differential pair circuit DP of the high-temperature side.

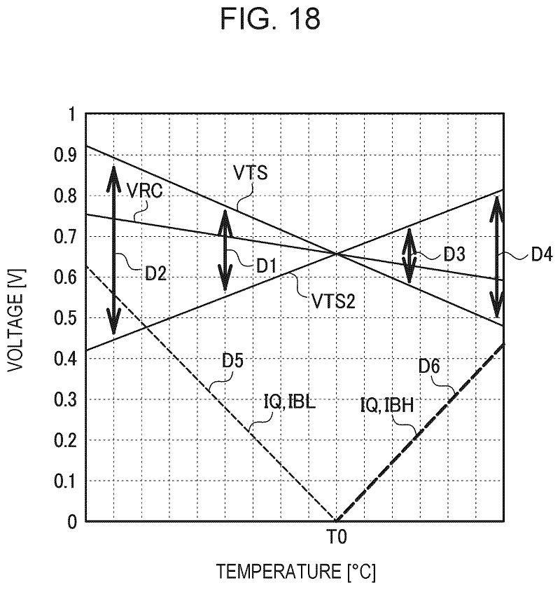

FIG. 18 is a temperature characteristic example for describing an operation of the tail current control circuit 70. As shown in FIG. 18, the temperature detection voltage VTS has a negative temperature characteristic. The voltage VTS2 output by the operational amplifier OPD2 of the first-order correction circuit 43 in FIG. 9 has a positive temperature characteristic. The voltage VTS2 can also be referred to as a temperature detection voltage. The reference voltage VRC input into the non-inverting input terminals of the operational amplifiers OPD1 and OPD2 which are first input terminals, in FIG. 1 has, for example, a negative temperature characteristic. For example, when the reference voltage generation circuit 60 in FIG. 2 generates the reference voltage VRC via a bandgap reference circuit, the reference voltage VRC generated by the bandgap reference circuit has a negative temperature characteristic when VDD reaches, for example, approximately 1.1 V because of reduction in the power supply voltage VDD.

As shown in Equation (12), when VTS>VTS2 is established, the tail current control circuit 70 of the low-temperature side generates the current IQ by converting a difference in voltage between the first voltage VA1=VTS and the second voltage VA2=VTS2 having a different temperature characteristic from the first voltage into a current. That is, VA1−VA2=VTS−VTS2 which is the difference in voltage shown by D1 and D2 in FIG. 18 is converted into the current IQ. Accordingly, the current IQ shown by D5 in FIG. 18 is generated in the temperature range of the low-temperature side, and the tail current corresponding to the current IQ flows through the differential pair circuit DP of the low-temperature side.

Accordingly, as shown by D5 in FIG. 18, the tail current that reaches, for example, zero which is the minimum current value, at the temperature TO of the inflection point of the temperature compensation voltage VCP and of which the current value increases as the temperature decreases from the temperature TO of the inflection point flows through the differential pair circuit DP of the low-temperature side. Here, as shown in Equation (15), the current IQ in the tail current control circuit 70 of high-temperature side is zero in the temperature range of the low-temperature side in which VT2<VTS is established. Accordingly, the tail current of the differential pair circuit DP of the high-temperature side does not flow in the temperature range of the low-temperature side, and an unnecessary current can be prevented from flowing in the differential pair circuit DP of the high-temperature side.

For example, in FIG. 5, the first tail current control circuit 71 generates the current IQ corresponding to the difference in voltage between VA1=VTS and VA2=VTS2 in the temperature range of the low-temperature side. That is, the current IQ shown by D5 corresponding to the difference in voltage between D1 and D2 in FIG. 18 is generated. Accordingly, the tail current IBL corresponding to the current IQ of D5 in FIG. 18 flows through the differential pair circuits DPL1 and DPL2 of the low-temperature side. That is, the tail current IBL of which the current value increases as the temperature decreases from the temperature TO of the inflection point flows through the differential pair circuits DPL1 and DPL2 of the low-temperature side. Here, as in Equation (15), the current IQ in the second tail current control circuit 72 is zero which is the minimum current value. Thus, the tail current IBH does not flow through the differential pair circuits DPH1 and DPH2 of the high-temperature side. Accordingly, an unnecessary current can be prevented from flowing in the differential pair circuits DPH1 and DPH2 of the high-temperature side in the temperature range of the low-temperature side.

As shown in Equation (14), when VTS2>VTS is established, the tail current control circuit 70 of the high-temperature side generates the current IQ by converting a difference in voltage between the first voltage VA1=VTS2 and the second voltage VA2=VTS having a different temperature characteristic from the first voltage into a current. That is, VA1−VA2=VTS2−VTS which is the difference in voltage shown by D3 and D4 in FIG. 18 is converted into the current IQ. Accordingly, the current IQ as shown by D6 is generated in the temperature range of the high-temperature side, and the tail current corresponding to the current IQ flows through the differential pair circuit DP of the high-temperature side.

Accordingly, as shown by D6 in FIG. 18, the tail current that reaches, for example, zero which is the minimum current value, at the temperature TO of the inflection point of the temperature compensation voltage and of which the current value increases as the temperature increases from the temperature TO of the inflection point flows through the differential pair circuit DP of the high-temperature side. Here, as shown in Equation (13), the current IQ in the tail current control circuit 70 of low-temperature side is zero in the temperature range of the high-temperature side in which VTS<VTS2 is established. Accordingly, the tail current of the differential pair circuit DP of the low-temperature side does not flow in the temperature range of the high-temperature side, and an unnecessary current can be prevented from flowing in the differential pair circuit DP of the low-temperature side.

For example, in FIG. 5, the second tail current control circuit 72 generates the current IQ corresponding to the difference in voltage between VA1=VTS2 and VA2=VTS in the temperature range of the high-temperature side. That is, the current IQ shown by D6 corresponding to the difference in voltage between D3 and D4 in FIG. 18 is generated. Accordingly, the tail current IBH corresponding to the current IQ of D6 in FIG. 18 flows through the differential pair circuits DPH1 and DPH2 of the high-temperature side. That is, the tail current IBH of which the current value increases as the temperature rises from the temperature TO of the inflection point flows through the differential pair circuits DPH1 and DPH2 of the high-temperature side. Here, as in Equation (13), the current IQ in the first tail current control circuit 71 is zero which is the minimum current value. Thus, the tail current IBL does not flow through the differential pair circuits DPL1 and DPL2 of the low-temperature side. Accordingly, an unnecessary current can be prevented from flowing in the differential pair circuits DPL1 and DPL2 of the low-temperature side in the temperature range of the high-temperature side.

In the example described above, VA1=VTS and VA2=VTS2 are set on the low-temperature side, and VA1=VTS2 and VA2=VTS are set on the high-temperature side as the voltages VA1 and VA2 of the tail current control circuit 70. However, the present embodiment is not limited to this. For example, in FIG. 18, VA1=VTS and VA2=VRC or VA1=VRC and VA2=VTS2 may be set on the low-temperature side. VA1=VTS2 and VA2=VRC or VA1=VRC and VA2=VTS may be set on the high-temperature side. In this case, the temperature characteristic of the reference voltage VRC is not limited to a negative temperature characteristic as in FIG. 18 and may be a flat temperature characteristic or a positive temperature characteristic.

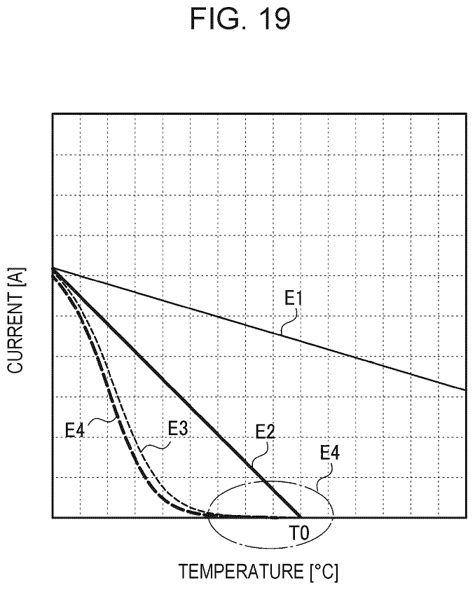

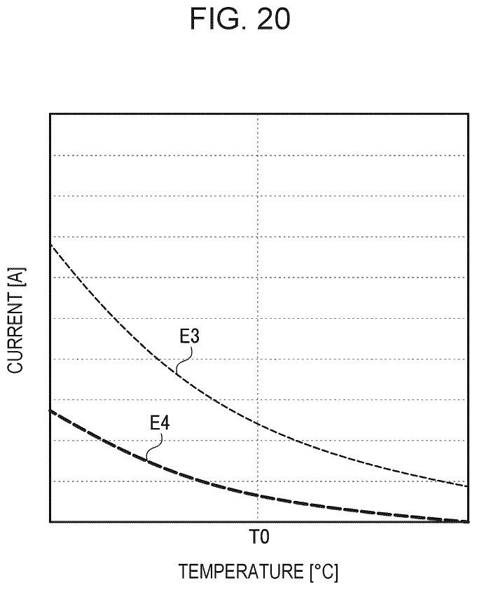

FIGS. 19 and 20 are descriptive diagrams of an effect of causing the tail current to have a temperature characteristic, and FIG. 20 is an enlarged view of the part shown by E4 in FIG. 19. E1 in FIG. 19 is the temperature characteristic of the tail current when not having a strong temperature characteristic, and E3 is the temperature characteristic of the current ITH of the differential pair circuit DP when the tail current of E1 flows. E2 in FIG. 19 is the temperature characteristic of the tail current when having a strong temperature characteristic, and E4 is the temperature characteristic of the current ITH of the differential pair circuit DP when the tail current of E2 flows.

As shown in FIG. 19, by causing the tail current to have a temperature characteristic stronger than E1, such as E2, the current ITH of the differential pair circuit DP can have a temperature characteristic steeper than E3, such as E4. In E1 in which the tail current does not have a strong temperature characteristic, or in E2 in which the tail current has a strong temperature characteristic, the way the current ITH flows through the differential pair circuit DP varies near room temperature which is near the temperature TO of the inflection point, as shown by E3 and E4 in FIG. 20.

For example, as shown in FIG. 11, a relationship of IB=ITH+IER is established between the currents ITH and IER and the tail current IB. The current IER is a current not contributing to temperature compensation and thus, is an unnecessary current. E1 and E2 in FIG. 19 show the tail current IB, and E3 and E4 show the current ITH. Accordingly, a current of a difference between E1 and E3 corresponds to the current IER when the tail current does not have a strong temperature characteristic, and a current of a difference between E2 and E4 corresponds to the current IER when the tail current has a strong temperature characteristic. Accordingly, by causing the tail current to have a strong temperature characteristic as shown by E2, the unnecessary current IER flowing through the differential pair circuit DP can be reduced, and reduction in the power consumption can be implemented.

As described above, as shown in FIGS. 1 and 2, the circuit device 20 of the present embodiment includes the oscillation circuit 30, the temperature compensation circuit 40, and the tail current control circuit 70. The oscillation circuit 30 generates the oscillation signal by causing the resonator 10 to oscillate. The temperature compensation circuit 40 includes the higher-order correction circuit 44 that generates the higher-order compensation current based on the temperature detection voltage VTS from the temperature detection circuit 50, and generates the temperature compensation voltage VCP of the oscillation frequency of the oscillation signal based on the higher-order compensation current. The higher-order correction circuit 44 includes the differential pair circuit DP, and the differential pair circuit DP generates the current for temperature compensation based on the temperature detection voltage VTS by controlling the tail current via the tail current control circuit 70. The tail current control circuit 70 controls the tail current of the differential pair circuit DP to reach the minimum current value at the temperature of the inflection point of the temperature compensation voltage and to have a current value that increases in accordance with a change in the temperature from the temperature of the inflection point. That is, as shown by D5 and D6 in FIG. 18 and Equations (12), (13), (14), and (15), the tail current of the differential pair circuit DP is controlled to reach, for example, zero which is the minimum current value, at the temperature (T0) of the inflection point and to have a current value that increases in accordance with a change in the temperature from the temperature of the inflection point. For example, as shown by D5 in FIG. 18, the tail current is controlled to have a current value that increases as the temperature decreases from the temperature (T0) of the inflection point. Alternatively, as shown by D6, the tail current is controlled to have a current value that increases as the temperature increases from the temperature of the inflection point.

According to the present embodiment, the tail current is controlled to reach the minimum current value at the temperature of the inflection point in the differential pair circuit DP that is provided in the higher-order correction circuit 44 which generates the higher-order compensation current, and that generates the current for temperature compensation. Accordingly, the higher-order compensation current flowing at the temperature of the inflection point can be sufficiently reduced, and adjustment of the characteristic of the higher-order compensation current and adjustment of the inflection point can be facilitated. In addition, since the tail current of the differential pair circuit DP is controlled to have a current value that increases in accordance with a change in the temperature from the temperature of the inflection point, the temperature characteristic of the current for temperature compensation generated by the differential pair circuit DP can be a steeper temperature characteristic. Accordingly, for example, even when the power supply voltage is reduced, a more appropriate higher-order compensation current can be generated, and reduction in the power consumption and the like of the circuit device 20 can be implemented.

As shown in FIGS. 2 and 5, the higher-order correction circuit 44 includes the first compensation circuit 47 and the second compensation circuit 48. The first compensation circuit 47 includes the differential pair circuit DPL (DPL1, DPL2) for the low-temperature side as a differential pair circuit, and the differential pair circuit DPL generates the current (IL) for temperature compensation of the low-temperature side. The second compensation circuit 48 includes the differential pair circuit DPH (DPH1, DPH2) for the high-temperature side as a differential pair circuit, and the differential pair circuit DPH generates the current (IH) for temperature compensation of the high-temperature side.

In this case, the higher-order compensation current can be generated by the current for temperature compensation generated by the differential pair circuit DPL of the first compensation circuit 47 in the temperature range of the low-temperature side, and the higher-order compensation current can be generated by the current for temperature compensation generated by the differential pair circuit DPH of the second compensation circuit 48 in the temperature range of the high-temperature side. Accordingly, in each temperature range of the low-temperature side and the high-temperature side, the current for generating the higher-order compensation current can be generated by each differential pair circuit of the low-temperature side and the high-temperature side using the tail current that reaches the minimum current value at the temperature of the inflection point and of which the current value increases in accordance with a change in the temperature.

As shown in FIGS. 2 and 5, the tail current control circuit 70 includes the first tail current control circuit 71 and the second tail current control circuit 72. As shown by D5 in FIG. 18 and Equations (12) and (13), the first tail current control circuit 71 controls the first tail current (IBL) of the differential pair circuit DPL to reach the minimum current value at the temperature (T0) of the inflection point and to have a current value that increases as the temperature decreases from the temperature of the inflection point. In addition, as shown by D6 in FIG. 18 and Equations (14) and (15), the second tail current control circuit 72 controls the second tail current (IBH) of the differential pair circuit DPH to reach the minimum current value at the temperature (T0) of the inflection point and to have a current value that increases as the temperature increases from the temperature of the inflection point.

In this case, the first tail current that reaches the minimum current value at the temperature of the inflection point and of which the current value increases as the temperature decreases from the temperature of the inflection point flows through the differential pair circuit DPL of the low-temperature side in the temperature range of the low-temperature side, and the current for generating the higher-order compensation current of the low-temperature side can be generated. Accordingly, appropriate temperature compensation in the temperature range of the low-temperature side can be implemented. In addition, the second tail current that reaches the minimum current value at the temperature of the inflection point and of which the current value increases as the temperature increases from the temperature of the inflection point flows through the differential pair circuit DPH of the high-temperature side in the temperature range of the high-temperature side, and the current for generating the higher-order compensation current of the high-temperature side can be generated. Accordingly, appropriate temperature compensation in the temperature range of the high-temperature side can be implemented.

The first tail current control circuit 71 controls the first tail current to reach the minimum current value when the temperature is higher than the temperature of the inflection point. The second tail current control circuit 72 controls the second tail current to reach the minimum current value when the temperature is lower than the temperature of the inflection point. That is, while the first tail current of the low-temperature side of the temperature characteristic as shown by D5 is generated when the temperature is lower than the temperature (T0) of the inflection point, the first tail current of the low-temperature side reaches the minimum current value when the temperature is higher than the temperature of the inflection point. In addition, while the second tail current of the high-temperature side of the temperature characteristic as shown by D6 is generated when the temperature is higher than the temperature of the inflection point, the second tail current of the high-temperature side reaches the minimum current value when the temperature is lower than the temperature of the inflection point.

In this case, when the temperature is higher than the temperature of the inflection point, the first tail current in the differential pair circuit DPL of the low-temperature side reaches the minimum current value. Thus, when temperature compensation on the high-temperature side is performed, flowing of an unnecessary current in the differential pair circuit DPL of the low-temperature side can be reduced. In addition, when the temperature is lower than the temperature of the inflection point, the second tail current in the differential pair circuit DPH of the high-temperature side reaches the minimum current value. Thus, when temperature compensation on the low-temperature side is performed, flowing of an unnecessary current in the differential pair circuit DPH of the high-temperature side can be reduced. Accordingly, reduction in the power consumption of the circuit device 20 can be implemented.

In the present embodiment, the current value of the first tail current increases with the first-order characteristic as the temperature decreases from the temperature of the inflection point, and the current value of the second tail current increases with the first-order characteristic as the temperature increases from the temperature of the inflection point. For example, as shown by D5 in FIG. 18, the current value of the first tail current (IBL) of the low-temperature side increases with the first-order characteristic as the temperature decreases from the temperature of the inflection point. In addition, as shown by D6, the current value of the second tail current (IBH) of the high-temperature side increases with the first-order characteristic as the temperature increases from the temperature of the inflection point.

In this case, the current value of the first tail current of the low-temperature side increases monotonically with the slope of the first-order characteristic as the temperature decreases from the temperature of the inflection point, and the current value of the second tail current of the high-temperature side increases monotonically with the slope of the first-order characteristic as the temperature increases from the temperature of the inflection point. Accordingly, the differential pair circuit DPL of the low-temperature side and the differential pair circuit DPH of the high-temperature side can generate the current for temperature compensation having a more steeper temperature characteristic based on the first tail current and the second tail current having the first-order temperature characteristic.

The minimum current value of the tail current is, for example, zero. That is, the tail current control circuit 70 controls the tail current to have a current value that reaches zero at the temperature of the inflection point and that increases in accordance with a change in the temperature from the temperature of the inflection point.

By causing the current value of the tail current in the differential pair circuit DP to reach zero at the temperature of the inflection point, adjustment of the characteristic of the higher-order compensation current and adjustment of the inflection point can be facilitated. In addition, since flowing of an unnecessary tail current through the differential pair circuit DP can be reduced, reduction in the power consumption of the circuit device 20 can be implemented.

As shown in FIG. 11, the tail current control circuit 70 generates the current IQ for controlling the tail current by converting the difference in voltage between the voltage VA1 which is the first voltage, and the voltage VA2 which is the second voltage having a different temperature characteristic from that of the voltage VA1, into a current. That is, as shown in Equations (10), (12), and (14), the tail current control circuit 70 generates the current IQ obtained by converting VA1-VA2 which is the difference in voltage between the voltage VAL and the voltage VA2, into a current.

In this case, as shown by D1 and D2 or D3 and D4 in FIG. 18, the tail current of which the current value increases as VA1−VA2 which is the difference in voltage between the voltage VA1 and the voltage VA2, increases in accordance with a change in the temperature from the temperature of the inflection point is generated. By generating the current for temperature compensation via the differential pair circuit DP using the tail current having such a strong temperature characteristic, an appropriate higher-order compensation current can be generated even when, for example, the power supply voltage is reduced.

The difference in voltage between the voltage VA1 which is the first voltage, and the voltage VA2 which is the second voltage, reaches zero at the temperature of the inflection point. For example, as shown in FIG. 18, when VA1=VTS and VA2=VTS2 are established on the low-temperature side, VA1−VA2=VTS−VTS2 reaches zero at the temperature of the inflection point. When VA1=VTS2 and VA2=VTS are established on the high-temperature side, VA1−VA2=VTS2−VTS reaches zero at the temperature of the inflection point.

In this case, by causing VA1-VA2 which is the difference in voltage between the voltage VA1 and the voltage VA2, to reach zero at the temperature of the inflection point, the current value of the current IQ generated by converting the difference in voltage into a current also reaches zero. Accordingly, the current value of the tail current flowing through the differential pair circuit DP can also be set to zero at the temperature of the inflection point. Adjustment of the characteristic of the higher-order compensation current and adjustment of the inflection point can be facilitated, and reduction in the power consumption and the like can be implemented.

As shown in FIGS. 3 and 9, the temperature compensation circuit 40 includes the first-order correction circuit 43 that performs first-order temperature compensation. As shown in FIG. 18 and Equations (12) to (15), the voltage VA1 which is the first voltage is a voltage of one of the temperature detection voltage VTS, the voltage VTS2 output by the operational amplifier OPD2 of the first-order correction circuit 43, or the reference voltages VRC for temperature compensation. The voltage VA2 which is the second voltage is a voltage different from the voltage of one of the temperature detection voltage VTS, the voltage VTS2, or the reference voltage VRC. For example, VA1=VTS and VA2=VTS2 are established in Equations (12) and (13), and VA1=VTS2 and VA2=VTS are established in Equations (14) and (15). In this case, one of the voltages VA1 and VA2 may be the reference voltage VRC for temperature compensation shown in FIG. 18.

In this case, by converting the difference in voltage between two voltages among the temperature detection voltage VTS, the voltage VTS2 output by the operational amplifier OPD2 of the first-order correction circuit 43, and the reference voltage VRC for temperature compensation into a current, the current IQ for controlling the tail current of the differential pair circuit DP can be generated. Accordingly, the tail current of the differential pair circuit DP can be controlled by effectively using the temperature detection voltage VTS, the voltage VTS2, and the reference voltage VRC.

The voltage VA1 which is the first voltage and the voltage VA2 which is the second voltage have the first-order temperature characteristic. For example, when the temperature detection voltage VTS, the voltage VTS2, and the reference voltage VRC in FIG. 18 are used as the voltages VA1 and VA2, the temperature detection voltage VTS, the voltage VTS2, and the reference voltage VRC have, for example, the first-order temperature characteristic such as a negative first-order temperature characteristic or a positive first-order temperature characteristic.

In this case, when the current IQ is generated by converting (VA1-VA2) which is the difference in voltage between the voltage VAL and the voltage VA2, into a current, the current IQ that changes linearly in response to a change in the temperature as shown by D5 and D6 in FIG. 18 can be generated. By using such a current IQ, the tail current that changes linearly in response to a change in the temperature can be caused to flow through the differential pair circuit DP.

As shown in FIG. 17, the tail current control circuit 70 includes the differential unit 74 and the output unit 75. The differential unit 74 includes the bipolar transistor TA4 controlled by the voltage VA1 and the bipolar transistor TA3 controlled by output of the output unit 75 as transistors of a differential pair. The bipolar transistor TA4 is the first transistor, and the bipolar transistor TA3 is the second transistor. The output of the output unit 75 is the node NA4. The output unit 75 includes the transistor TA6 that is provided between the node of VDL that is a power supply node, and the node NA4 and that is controlled by output of the differential unit 74, and the resistor RA provided between the node NA4 and the input node of the voltage VA2. The node NA4 is a first node. The output of the differential unit 74 is the node NA2 and is, for example, the output voltage VAQ. The output unit 75 may include the transistor TA7 that is provided between the node of VDL and the node NA5 and that is controlled by the output of the differential unit 74, and the bipolar transistor TA8 that is provided between the node NA5 and the node of VSS and of which the base and the collector are coupled to the node NA5.

According to the tail current control circuit 70 having such a configuration, the voltage of the node NA4 which is the first node is set to the voltage VA1 by virtually grounding the differential unit 74. Thus, a current corresponding to (VA1-VA2) which is the difference in voltage between the voltage VA1 and the voltage VA2 can flow through the resistor RA. The tail current of the differential pair circuit DP can be controlled by the current IQ corresponding to the current flowing through the resistor RA.

### 3. Modification Example

While the circuit device 20 and the oscillator 4 of the present embodiment are described above, the present embodiment is not limited to this, and various modifications can be made.

For example, FIGS. 5 and 18 mainly show an example in which a method of controlling the tail current of the present embodiment to have a current value that increases in accordance with a change in the temperature from the temperature of the inflection point is performed in the temperature range of the low-temperature side and the temperature range of the high-temperature side. However, the method of controlling the tail current of the present embodiment can also be performed in only one temperature range or in three or more temperature ranges.

The configuration of the differential pair circuit DP is not limited to the configuration shown in FIG. 11, and various modifications can be made. For example, bipolar transistors of p-n-p may be used as transistors of a differential pair instead of bipolar transistors of n-p-n. Alternatively, an N-type MOS transistor or a P-type MOS transistor may be used instead of a bipolar transistor. A MOS transistor may be used as a transistor of a current source instead of a bipolar transistor.

The configuration of the tail current control circuit 70 is not limited to the configuration shown in FIG. 17, and various modifications can be made. For example, bipolar transistors of p-n-p may be used as transistors of a differential pair of the differential unit 74 instead of bipolar transistors of n-p-n. Alternatively, an N-type MOS transistor or a P-type MOS transistor may be used instead of a bipolar transistor. A bipolar transistor may be used as a transistor of a current source instead of a MOS transistor.

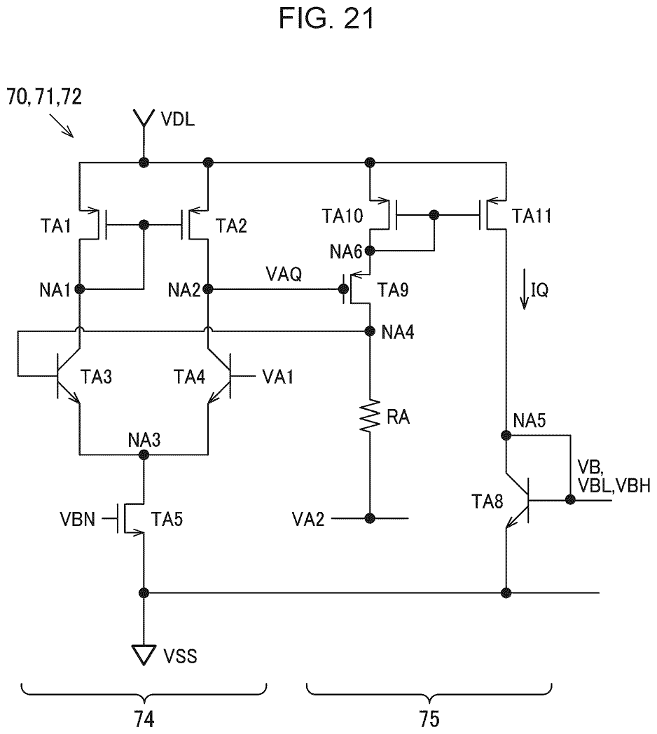

The configuration of the output unit 75 of the tail current control circuit 70 is not limited to the configuration shown in FIG. 17. For example, FIG. 21 shows another configuration example of the tail current control circuit 70. In FIG. 21, transistors TA9, TA10, and TA11 are provided instead of the transistors TA6 and TA7 in FIG. 17. The transistors TA10 and TA9 are provided in series between the node of VDL and the node NA4 of one end of the resistor RA. The transistor TA11 and the bipolar transistor TA8 are provided in series between the node of VDL and the node of VSS. A gate of the transistor TA9 is coupled to the node NA2 which is the output of the differential unit 74. Gates of the transistors TA10 and TA11 are coupled to a node NA6 between the transistor TA10 and the transistor TA9. A drain of the transistor TA11 is coupled to the node NA5 to which the collector and the base of the bipolar transistor TA8 are coupled.

In FIG. 21, the output unit 75 is changed to a cascade configuration and operates as a two-staged amplifier. Thus, a higher gain than that in FIG. 17 can be implemented. In the configuration in FIG. 21, a difference in voltage between a voltage range of the voltage VAL and the power supply voltage VDL needs to be increased to secure VGS that is a gate-source voltage of the cascade stages of the output unit 75.

As described above, a circuit device of the present embodiment includes an oscillation circuit that generates an oscillation signal by causing a resonator to oscillate, a temperature compensation circuit that includes a higher-order correction circuit which generates a higher-order compensation current based on a temperature detection voltage from a temperature detection circuit, and that generates a temperature compensation voltage of an oscillation frequency of the oscillation signal based on the higher-order compensation current, and a tail current control circuit. The higher-order correction circuit includes a differential pair circuit that generates a current for temperature compensation based on the temperature detection voltage by controlling a tail current via the tail current control circuit. The tail current control circuit controls the tail current to reach a minimum current value at a temperature of an inflection point of the temperature compensation voltage and to have a current value that increases in accordance with a change in a temperature from the temperature of the inflection point.

According to the present embodiment, since the tail current is controlled to reach the minimum current value at the temperature of the inflection point, the higher-order compensation current flowing at the temperature of the inflection point can be reduced. In addition, since the tail current is controlled to have a current value that increases in accordance with a change in the temperature from the temperature of the inflection point, a temperature characteristic of the current for temperature compensation generated by the differential pair circuit can be a steeper temperature characteristic.

In the present embodiment, the higher-order correction circuit may include a first compensation circuit that includes a first differential pair circuit for a low-temperature side as a differential pair circuit and that generates a current for temperature compensation of the low-temperature side via the first differential pair circuit, and a second compensation circuit that includes a second differential pair circuit for a high-temperature side as a differential pair circuit and that generates a current for temperature compensation of the high-temperature side via the second differential pair circuit.

In this case, the higher-order compensation current can be generated by the current for temperature compensation generated by the differential pair circuit of the first compensation circuit in a temperature range of the low-temperature side, and the higher-order compensation current can be generated by the current for temperature compensation generated by the differential pair circuit of the second compensation circuit in a temperature range of the high-temperature side.

In the present embodiment, the tail current control circuit may include a first tail current control circuit that controls a first tail current of the first differential pair circuit to reach the minimum current value at the temperature of the inflection point of the temperature compensation voltage and to have a current value that increases as the temperature decreases from the temperature of the inflection point. The tail current control circuit may also include a second tail current control circuit that controls a second tail current of the second differential pair circuit to reach the minimum current value at the temperature of the inflection point of the temperature compensation voltage and to have a current value that increases as the temperature increases from the temperature of the inflection point.

In this case, appropriate temperature compensation in the temperature range of the low-temperature side and appropriate temperature compensation in the temperature range of the high-temperature side can be implemented.

In the present embodiment, the first tail current control circuit may control the first tail current to reach the minimum current value when the temperature is higher than the temperature of the inflection point, and the second tail current control circuit may control the second tail current to reach the minimum current value when the temperature is lower than the temperature of the inflection point.

In this case, flowing of an unnecessary current in the differential pair circuit of the low-temperature side can be reduced when temperature compensation is performed on the high-temperature side, and flowing of an unnecessary current in the differential pair circuit of the high-temperature side can be reduced when temperature compensation is performed on the low-temperature side.

In the present embodiment, the current value of the first tail current may increase with a first-order characteristic as the temperature decreases from the temperature of the inflection point, and the current value of the second tail current may increase with the first-order characteristic as the temperature increases from the temperature of the inflection point.

In this case, the differential pair circuit of the low-temperature side and the differential pair circuit of the high-temperature side can generate the current for temperature compensation having a more steeper temperature characteristic based on the first tail current and the second tail current having the first-order temperature characteristic.

In the present embodiment, the minimum current value may be zero.

In this case, adjustment of a characteristic of the higher-order compensation current and adjustment of the inflection point can be facilitated, or reduction in power consumption and the like of the circuit device can be implemented.

In the present embodiment, the tail current control circuit may generate a current for controlling the tail current by converting a difference in voltage between a first voltage and a second voltage having a different temperature characteristic from the first voltage into a current.

In this case, the tail current of which the current value increases as the difference in voltage between the first voltage and the second voltage increases because of a change in the temperature from the temperature of the inflection point can be generated.

In the present embodiment, the difference in voltage between the first voltage and the second voltage may reach zero at the temperature of the inflection point.

In this case, by causing the difference in voltage between the first voltage and the second voltage to reach zero at the temperature of the inflection point, a current value of the current generated by converting the difference in voltage into a current can also reach zero.

In the present embodiment, the temperature compensation circuit may include a first-order correction circuit that performs first-order temperature compensation, and the first voltage may be a voltage of one of the temperature detection voltage, a voltage output by an operational amplifier of the first-order correction circuit, or a reference voltage for temperature compensation. The second voltage may be a voltage different from the first voltage among the temperature detection voltage, the voltage output by the operational amplifier of the first-order correction circuit, and the reference voltage for temperature compensation.

In this case, the tail current of the differential pair circuit can be controlled by effectively using the temperature detection voltage, the voltage output by the operational amplifier of the first-order correction circuit, and the reference voltage for temperature compensation.

In the present embodiment, the first voltage and the second voltage may have a first-order temperature characteristic.

In this case, the tail current that changes linearly in response to a change in the temperature can flow through the differential pair circuit.

In the present embodiment, the tail current control circuit may include a differential unit and an output unit, and the differential unit may include a first transistor controlled by the first voltage and a second transistor controlled by output of the output unit as transistors of a differential pair. The output unit may include a transistor that is provided between a power supply node and a first node and that is controlled by output of the differential unit, and a resistor that is provided between the first node and an input node of the second voltage.

According to the tail current control circuit having such a configuration, a voltage of the first node is set to the first voltage by virtually grounding the differential unit. Thus, the tail current of the differential pair circuit can be controlled by a current corresponding to a current flowing through the resistor by causing a current corresponding to the difference in voltage between the first voltage and the second voltage to flow through the resistor.

An oscillator of the present embodiment includes the above circuit device, and the resonator.

While the present embodiment is described in detail as described above, those skilled in the art will easily understand that various modifications can be made without substantially departing from novel matters and effects of the present disclosure. Accordingly, all such modification examples should be construed as falling within the scope of the present disclosure. For example, a term described at least once in the specification or the drawings together with a different term having a broader meaning or the same meaning can be replaced with the different term anywhere in the specification or the drawings. All combinations of the present embodiment and the modification examples also fall within the scope of the present disclosure. The configurations, operations, and the like of the circuit device and the oscillator are not limited to those described in the present embodiment, and various modifications can be made.

What is claimed is:

1. A circuit device comprising:
an oscillation circuit that generates an oscillation signal by causing a resonator to oscillate;
a temperature compensation circuit that includes a higher-order correction circuit which generates a higher-order compensation current based on a temperature detection voltage from a temperature detection circuit, and that generates a temperature compensation voltage of an oscillation frequency of the oscillation signal based on the higher-order compensation current; and
a tail current control circuit, wherein
the higher-order correction circuit includes a differential pair circuit that generates a current for temperature compensation based on the temperature detection voltage by controlling a tail current via the tail current control circuit, and
the tail current control circuit controls the tail current to reach a minimum current value at a temperature of an inflection point of the temperature compensation voltage and to have a current value that increases in accordance with a change in a temperature from the temperature of the inflection point.

2. The circuit device according to claim 1, wherein
the higher-order correction circuit includes
a first compensation circuit that includes a first differential pair circuit for a low-temperature side as the differential pair circuit and that generates a current for temperature compensation of the low-temperature side via the first differential pair circuit, and
a second compensation circuit that includes a second differential pair circuit for a high-temperature side as the differential pair circuit and that generates a current for temperature compensation of the high-temperature side via the second differential pair circuit.

3. The circuit device according to claim 2, wherein
the tail current control circuit includes
a first tail current control circuit that controls a first tail current of the first differential pair circuit to reach the minimum current value at the temperature of the inflection point of the temperature compensation voltage and to have a current value that increases as the temperature decreases from the temperature of the inflection point, and
a second tail current control circuit that controls a second tail current of the second differential pair circuit to reach the minimum current value at the temperature of the inflection point of the temperature compensation voltage and to have a current value that increases as the temperature increases from the temperature of the inflection point.

4. The circuit device according to claim 3, wherein
the first tail current control circuit controls the first tail current to reach the minimum current value when the temperature is higher than the temperature of the inflection point, and
the second tail current control circuit controls the second tail current to reach the minimum current value when the temperature is lower than the temperature of the inflection point.

5. The circuit device according to claim 3, wherein
the current value of the first tail current increases with a first-order characteristic as the temperature decreases from the temperature of the inflection point, and
the current value of the second tail current increases with the first-order characteristic as the temperature increases from the temperature of the inflection point.

6. The circuit device according to claim 1, wherein
the minimum current value is zero.

7. The circuit device according to claim 1, wherein
the tail current control circuit generates a current for controlling the tail current by converting a difference in voltage between a first voltage and a second voltage having a different temperature characteristic from the first voltage into a current.

8. The circuit device according to claim 7, wherein
the difference in voltage between the first voltage and the second voltage reaches zero at the temperature of the inflection point.

9. The circuit device according to claim 7, wherein
the temperature compensation circuit includes a first-order correction circuit that performs first-order temperature compensation,
the first voltage is a voltage of one of the temperature detection voltage, a voltage output by an operational amplifier of the first-order correction circuit, or a reference voltage for temperature compensation, and
the second voltage is a voltage different from the first voltage among the temperature detection voltage, the voltage output by the operational amplifier of the first-order correction circuit, and the reference voltage for temperature compensation.

10. The circuit device according to claim 7, wherein
the first voltage and the second voltage have a first-order temperature characteristic.

11. The circuit device according to claim 7, wherein
the tail current control circuit includes a differential unit and an output unit,
the differential unit includes a first transistor controlled by the first voltage and a second transistor controlled by output of the output unit as transistors of a differential pair, and
the output unit includes
a transistor that is provided between a power supply node and a first node and that is controlled by output of the differential unit, and
a resistor that is provided between the first node and an input node of the second voltage.

12. An oscillator comprising:
the circuit device according to claim 1; and
the resonator.
